(19) United States
(12) Patent Application Publication
(10) Pub. No.: US 2026/0173730 A1
(43) Pub. Date: Jun. 18, 2026

(54) DISPLAY PANEL AND DISPLAY DEVICE

(71) Applicants: Kunshan Govisionox Optoelectronics Co., Ltd., Kunshan (CN); Hefei Visionox Electronics Co., Ltd., Hefei (CN)

(72) Inventors: Chung-Chun LEE, Kunshan (CN); Yuan YAO, Kunshan (CN); Aihua XUE, Kunshan (CN); Chaoran QIN, Kunshan (CN)

(73) Assignees: Kunshan Govisionox Optoelectronics Co., Ltd., Kunshan (CN); Hefei Visionox Electronics Co., Ltd., Hefei (CN)

(21) Appl. No.: 19/419,978

(22) Filed: Dec. 15, 2025

Related U.S. Application Data
(63) Continuation of application No. PCT/CN2025/132475, filed on Nov. 4, 2025.

(30) Foreign Application Priority Data
Dec. 13, 2024 (CN) 202411845442.6

(51) Int. Cl. H10K 59/80; H10K 59/122

(52) U.S. Cl. CPC H10K 59/873; H10K 59/122

(57) ABSTRACT

A display panel and a display device. The display panel includes a substrate; an isolation structure defining an isolation opening, the isolation structure includes an isolation segment, the isolation segment divides the isolation opening into at least two sub-openings; a light-emitting layer including a plurality of light-emitting units, at least one of the plurality of light-emitting units includes at least two sub-units disposed separately, each of the sub-units includes a first sub-electrode, a light-emitting sub-structure, and a second sub-electrode sequentially stacked in a direction away from the substrate; and a first encapsulation layer including an encapsulation portion. The first sub-electrodes of a plurality of sub-units in the same light-emitting unit are electrically connected to each other, and an orthographic projection of at least a portion of the isolation segment on the substrate is located within an orthographic projection of the encapsulation portion on the substrate.

### CROSS REFERENCE TO RELATED APPLICATIONS

This application is a continuation of International Application No. PCT/CN 2025/132475, filed on Nov. 4, 2025, which claims priority to Chinese Patent Application No. 202411845442.6, titled “DISPLAY PANEL AND DISPLAY DEVICE”, filed on Dec. 13, 2024, both of which are hereby incorporated by reference in their entireties.

### FIELD

The present application relates to the field of display, and in particular, to a display panel and a display device.

### BACKGROUND

Organic Light Emitting Diode (OLED) and planar display device based on technology such as Light Emitting Diode (LED) are widely used in various consumer electronic products such as mobile phones, televisions, notebook computers, and desktop computers due to advantages such as high image quality, power saving, thin body, and wide application range, and have become mainstream in display devices. In the traditional display panel manufacturing process, light-emitting pixels are typically patterned using a Fine Metal Mask (FMM). FMM technology is mature and has extensive mass production experience. However, FMM technology also has issues such as limited precision, high development costs, and long development cycles. Mask-free technology eliminates the limitations of traditional OLED processes on display size, resolution, and other screen performance, offering advantages such as high performance, full-size capability, and agile delivery. Patents CN118251982A, CN115666161A, CN116648095A, CN117062489A, CN118678742A, CN118785761A, CN115224220A, CN118678729A, CN118660529A, and CN118660589A document related content of mask-free technology for reference.

However, the performance of current OLED display products needs to be improved.

### SUMMARY

Embodiments of the present application provide a display panel and a display device.

A first aspect of embodiments of the present application provides a display panel, the display panel including: a substrate; an isolation structure located on one side of the substrate, wherein the isolation structure defines an isolation opening, the isolation structure includes an isolation segment, the isolation segment is disposed within at least one isolation opening and divides the isolation opening into at least two sub-openings; a light-emitting layer located on one side of the substrate, wherein the light-emitting layer includes a plurality of light-emitting units, at least a portion of the light-emitting unit is located within the isolation opening, at least one of the plurality of light-emitting units includes at least two sub-units disposed separately, at least a portion of the sub-unit is located within the sub-opening, each of the sub-units includes a first sub-electrode, a light-emitting sub-structure, and a second sub-electrode sequentially stacked in a direction away from the substrate; and a first encapsulation layer including an encapsulation portion for encapsulating the light-emitting units; wherein the first sub-electrodes of a plurality of sub-units in the same light-emitting unit are electrically connected to each other, and an orthographic projection of at least a portion of the isolation segment on the substrate is located within an orthographic projection of the encapsulation portion on the substrate.

A first aspect of embodiments of the present application provides a display panel, the display panel including: a substrate; an isolation structure located on one side of the substrate, wherein the isolation structure defines and forms an isolation opening, the isolation structure includes an isolation segment, the isolation segment is disposed within at least one isolation opening and divides the isolation opening into at least two sub-openings; a light-emitting layer located on one side of the substrate, wherein the light-emitting layer includes light-emitting units with at least a portion of the light-emitting unit located within the isolation opening, at least one of the light-emitting units includes two or more sub-units disposed separately, at least a portion of the sub-unit is located within the sub-opening, each of the sub-units includes a first sub-electrode, a light-emitting sub-structure, and a second sub-electrode sequentially stacked in a direction away from the substrate; and a first encapsulation layer including an encapsulation portion for encapsulating the light-emitting units, the encapsulation portion including sub-encapsulation portions for encapsulating the sub-units, wherein the first sub-electrodes of a plurality of sub-units in the same light-emitting unit are electrically connected to each other, and an orthographic projection of the isolation segment on the substrate is partially overlapped with an orthographic projection of the sub-encapsulation portion on the substrate.

A second aspect of embodiments of the present application provides a display device, including the display panel according to any of the above embodiments.

According to the display panel of the embodiments of the present application, the display panel includes a substrate, an isolation structure, a light-emitting layer, and a first encapsulation layer. The isolation structure defines isolation openings, and isolation segments are disposed within the isolation openings, capable of dividing the isolation openings into two or more sub-openings. At least a portion of the light-emitting unit of the light-emitting layer is located within the isolation opening. The light-emitting units include two or more sub-units disposed separately, at least a portion of the sub-unit is located within the sub-opening, and the isolation segments are located between adjacent sub-units. Each sub-unit includes a first sub-electrode, a light-emitting sub-structure, and a second sub-electrode, wherein the first sub-electrode and the second sub-electrode are configured to drive the light-emitting sub-structure to emit light. The encapsulation portion of the first encapsulation layer provides encapsulation protection for the light-emitting units. The first sub-electrodes of the plurality of sub-units in the same light-emitting unit are electrically connected to each other, enabling the plurality of sub-units of the same light-emitting unit to be driven by the same pixel circuit, which can simplify the structure of the pixel circuit. The orthographic projection of at least a portion of the isolation segment on the substrate is located within the orthographic projection of the encapsulation portion on the substrate, that is, the encapsulation portion also covers the isolation segments located between adjacent sub-openings.

### BRIEF DESCRIPTION OF THE DRAWINGS

By reading the following detailed description of non-limiting embodiments with reference to the drawings, other features, purposes, and advantages of the present application will become more apparent, wherein the same or similar reference numerals denote the same or similar features, and the drawings are not drawn to scale.

FIG. 1 is a structural schematic diagram of a display panel according to an embodiment of the present application.

FIG. 2 is a cross-sectional view taken along line A-A in FIG. 1.

FIG. 3 is a partially enlarged structural schematic diagram of FIG. 2 in an example.

FIG. 4 is a structural schematic diagram of a display panel according to another embodiment of the present application.

FIG. 5 is a partially enlarged structural schematic diagram of FIG. 4 in an example.

FIG. 6 is a structural schematic diagram of a display panel according to an embodiment of the present application.

FIG. 7 is a structural schematic diagram of a display panel according to yet another embodiment of the present application.

FIG. 8 is a partially enlarged structural schematic diagram of FIG. 2 in another example.

FIG. 9 is a structural schematic diagram of a display panel according to still another embodiment of the present application.

FIG. 10 is a structural schematic diagram of a display panel according to an embodiment of the present application.

FIG. 11 is a structural schematic diagram of a display panel according to yet another embodiment of the present application.

FIG. 12 is a cross-sectional view taken along line B-B in FIG. 11.

FIG. 13 is a structural schematic diagram of a display panel according to still another embodiment of the present application.

FIG. 14 is a structural schematic diagram of a display panel according to still another embodiment of the present application.

FIG. 15 is a structural schematic diagram of a display panel according to still another embodiment of the present application.

FIG. 16 is a structural schematic diagram of a display panel according to still another embodiment of the present application.

FIG. 17 is a cross-sectional view taken along line C-C in FIG. 1.

FIG. 18 is a structural schematic diagram of a first sub-electrode of a display panel according to an embodiment of the present application.

FIG. 19 is a structural schematic diagram of a first sub-electrode of a display panel according to another embodiment of the present application.

Description of reference numerals:
10, scan signal line; 20, data signal line;
100, substrate; 110, pixel circuit; 120, first insulation layer; 121, connection via;
200, isolation structure; 201, first sub-layer; 202, second sub-layer; 203, third sub-layer;
210, isolation opening; 210a, sub-opening; 211, first isolation opening; 212, second isolation opening; 213, third isolation opening;
220, isolation segment; 221, first isolation segment; 222, second isolation segment; 223, third isolation segment; 230, isolation portion;
300, light-emitting layer; 310, light-emitting unit; 310a, sub-unit; 311, first light-emitting unit; 312, second light-emitting unit; 313, third light-emitting unit; 320, pixel defining portion; 330, pixel opening; 330a, pixel sub-opening; 301, first electrode;
301a, first sub-electrode; 302, light-emitting structure; 302a, light-emitting sub-structure; 303, second electrode; 303a, second sub-electrode; 340, redundant unit;
400, first encapsulation layer; 410, encapsulation portion; 410a, sub-encapsulation portion; 411, first sub-encapsulation portion;
412, second sub-encapsulation portion; 413, third sub-encapsulation portion;
510, second encapsulation layer; 520, third encapsulation layer;
LD, continuous region; JD, overlapping region; S1, virtual quadrilateral; L1, diagonal; X, first direction; Y, second direction; P, third direction; Q, fourth direction; AA, display area; BA, bonding area; d1, first spacing; d2, second spacing; d3, third spacing.

### DETAILED DESCRIPTION

The features and exemplary embodiments of various aspects of the present application will be described in detail below. In order to make the purposes, technical solutions, and advantages of the present application clearer, the present application is further described in detail below with reference to the drawings and specific embodiments. It should be understood that the specific embodiments described herein are only configured to explain the present application and are not configured to limit the present application. For those skilled in the art, the present application can be implemented without some of these specific details. The following description of the embodiments is merely to provide a better understanding of the present application by showing examples of the present application.

It should be understood that when describing the structure of a component, when a layer or a region is referred to as being “on” or “above” another layer or another region, it may mean directly on the other layer or another region, or there may be other layers or regions between it and the other layer or another region. Moreover, if the component is flipped, the layer or region will be “under” or “below” the other layer or another region.

Embodiments of the present application provide a display panel, a display device, and a method for manufacturing the display panel. The embodiments of the display panel, the display device, and the method for manufacturing the display panel will be described below with reference to the drawings.

An embodiment of the present application provides a display panel, which may be an Organic Light Emitting Diode (OLED) display panel.

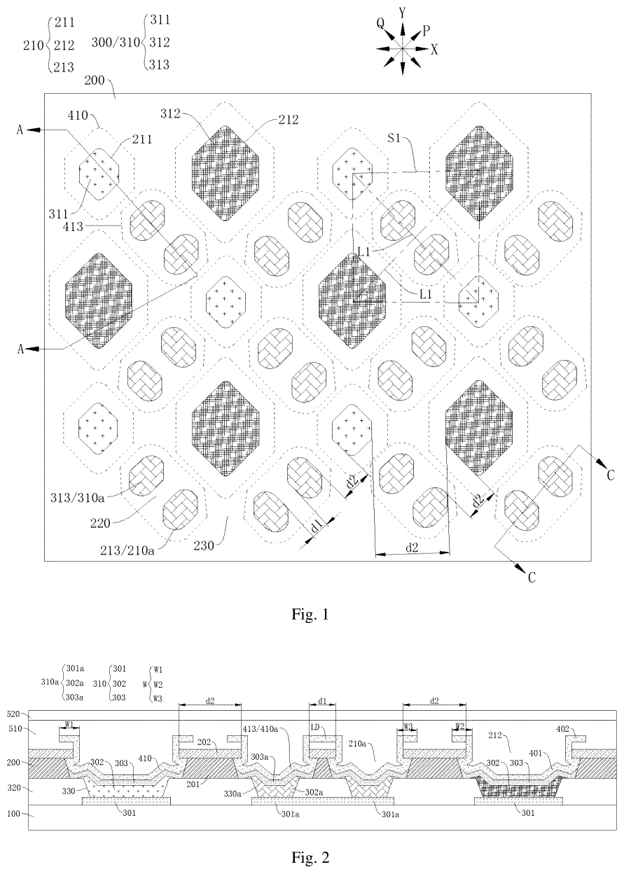

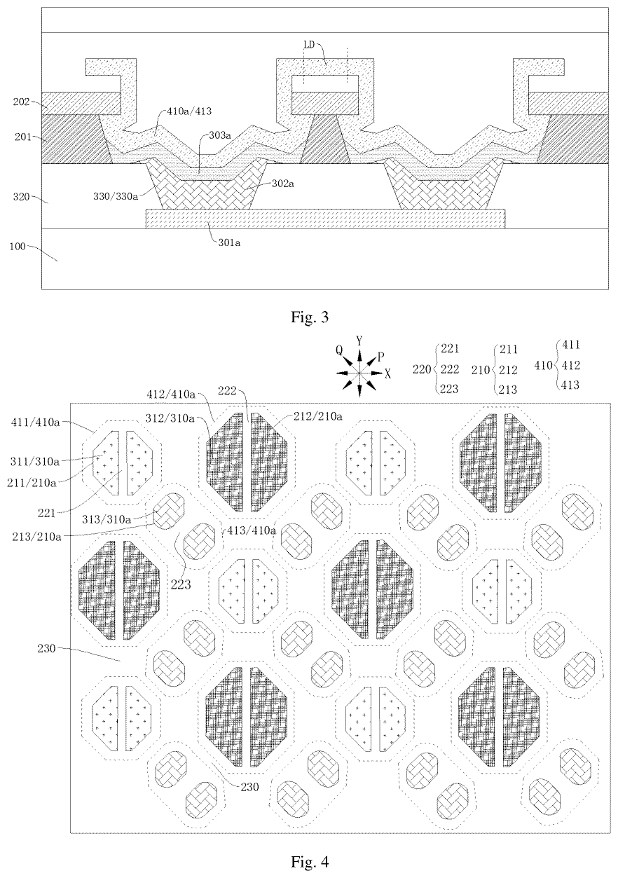

Referring to FIG. 1 to FIG. 3 together. FIG. 1 is a partial cross-sectional view of a display panel according to an embodiment of the present application; FIG. 2 is a cross-sectional view taken along line A-A in FIG. 1 in an example; FIG. 3 is a partially enlarged structural schematic diagram of FIG. 2.

As shown in FIG. 1 to FIG. 3, a first aspect of embodiments of the present application provides a display panel. The display panel includes: a substrate 100; an isolation structure 200 located on one side of the substrate 100, wherein the isolation structure 200 defines an isolation opening 210, the isolation structure 200 includes an isolation segment 220, the isolation segment 220 is disposed within at least one isolation opening 210 and divides the isolation opening 210 into at least two sub-openings 210a; a light-emitting layer 300 located on one side of the substrate 100, wherein the light-emitting layer 300 includes a plurality of light-emitting units 310, at least a portion of the light-emitting unit 310 is located within the isolation opening 210, at least one of the plurality of light-emitting units 310 includes at least two sub-units 310a disposed separately, at least a portion of the sub-unit 310a is located within the sub-opening 210a, each of the sub-units 310a includes a first sub-electrode 301a, a light-emitting sub-structure 302a, and a second sub-electrode 303a sequentially stacked in a direction away from the substrate 100; and a first encapsulation layer 400 including an encapsulation portion 410 for encapsulating the light-emitting units 310; wherein the first sub-electrodes 301a of a plurality of sub-units 310a in the same light-emitting unit 310 are electrically connected to each other, and an orthographic projection of at least a portion of the isolation segment 220 on the substrate 100 is located within an orthographic projection of the encapsulation portion 410 on the substrate 100.

According to the display panel of the embodiments of the present application, the display panel includes a substrate 100, an isolation structure 200, a light-emitting layer 300, and a first encapsulation layer 400. The isolation structure 200 defines isolation openings 210, and isolation segments 220 are disposed within the isolation openings 210, capable of dividing the isolation openings 210 into two or more sub-openings 210a. At least a portion of the light-emitting unit 310 of the light-emitting layer 300 is located within the isolation opening 210. The light-emitting units 310 include two or more sub-units 310a disposed separately, at least a portion of the sub-unit 310a is located within the sub-opening 210a, and the isolation segments 220 are located between adjacent sub-units 310a. Each sub-unit 310a includes a first sub-electrode 301a, a light-emitting sub-structure 302a, and a second sub-electrode 303a, wherein the first sub-electrode 301a and the second sub-electrode 303a are configured to drive the light-emitting sub-structure 302a to emit light. The encapsulation portion 410 of the first encapsulation layer 400 provides encapsulation protection for the light-emitting units 310. The first sub-electrodes 301a of the plurality of sub-units 310a in the same light-emitting unit 310 are electrically connected to each other, enabling the plurality of sub-units 310a of the same light-emitting unit 310 to be driven by the same pixel circuit 110, which can simplify the structure of the pixel circuit 110. The orthographic projection of at least a portion of the isolation segment 220 on the substrate 100 is located within the orthographic projection of the encapsulation portion 410 on the substrate 100, that is, the encapsulation portion 410 also covers the isolation segments 220 located between adjacent sub-openings 210a, which can increase the distribution area of the encapsulation portion 410, improve the encapsulation effect, and thereby improve the yield and performance of the display panel.

Moreover, in the embodiments of the present application, by dividing the same light-emitting unit 310 into two or more sub-units 310a, when one of the sub-units 310a fails, the remaining sub-units 310a can still continue to emit light, thereby avoiding display defects caused by the complete failure of the same light-emitting unit 310, and improving the display effect of the display panel.

Optionally, the display panel further includes a pixel definition layer, the pixel definition layer includes a pixel defining portion 320 and a pixel opening 330 defined by the pixel defining portion 320, the pixel opening 330 is in communication with the isolation opening 210, and at least a portion of the light-emitting unit 310 may be located within the pixel opening 330 in the isolation opening 210, so that the light-emitting units 310 can emit light through the isolation opening 210. Optionally, the isolation structure 200 may be located on a side of the pixel defining portion 320 away from the substrate 100, or the pixel defining portion 320 is provided with a recess, and the isolation structure 200 is located within the recess. Optionally, the pixel opening 330 includes a pixel sub-opening 330a corresponding to the sub-opening 210a, and the pixel sub-opening 330a is in communication with the sub-opening 210a.

Optionally, the light-emitting unit 310 includes a first electrode 301, a light-emitting structure 302, and a second electrode 303. As the light-emitting unit 310 includes a plurality of sub-units 310a, the first sub-electrodes 301a of the plurality of sub-units 310a constitute the first electrode 301 of the light-emitting unit 310, the light-emitting sub-structures 302a of the plurality of sub-units 310a constitute the light-emitting structure 302 of the light-emitting unit 310, and the second sub-electrodes 303a of the plurality of sub-units 310a constitute the second electrode 303 of the light-emitting unit 310.

The isolation structure 200 may be configured in various ways. The isolation structure 200 may be a single-layer structure and the cross-section of the isolation structure 200 may be inverted trapezoidal, i.e., the cross-section of the isolation structure 200 gradually decreases in a direction toward the substrate 100, so as to form a recess on a side of the isolation structure 200 facing the isolation opening 210. The recess is configured to block the light-emitting material to form independent light-emitting sub-structures 302a. At this time, the isolation opening 210 and the sub-openings 210a are defined by a single-layer structure.

In other optional embodiments, the isolation structure 200 includes a first sub-layer 201 and a second sub-layer 202 located on a side of the first sub-layer 201 away from the substrate 100, and the first sub-layer 201 is located within an orthographic projection of the second sub-layer 202 on the substrate 100. The second sub-layer 202 protrudes relative to the first sub-layer 201 toward the isolation opening 210, so as to form a recess on a side of the second sub-layer 202 facing the substrate 100, the recess is configured to block the light-emitting material to form independent light-emitting sub-structures 302a. As the isolation structure 200 includes a plurality of layers such as the first sub-layer 201 and the second sub-layer 202, the plurality of isolation openings 210 and sub-openings 210a are defined by the same layer, for example, both the sub-openings 210a and the isolation opening 210 are defined by the second sub-layer 202, i.e., an edge of the second sub-layer 202 in the orthographic projection on the substrate 100 completely coincides with an edge of the isolation opening 210 in the orthographic projection on the substrate 100. In other embodiments, the openings and the isolation opening 210 may also be defined by the first sub-layer 201.

Optionally, the isolation opening 210 and the light-emitting unit 310 correspond to each other, the same isolation opening 210 corresponds to the plurality of sub-units 310a of the same light-emitting unit 310, the light-emitting sub-structures 302a of the plurality of sub-units 310a of the same light-emitting unit 310 are located in the plurality of sub-openings 210a of the same isolation opening 210, and one sub-opening 210a is configured to accommodate one light-emitting sub-structure 302a. The isolation segment 220 refers to a portion of the isolation structure 200 located within the same isolation opening 210 and between two adjacent sub-openings 210a.

Optionally, the display panel further includes a second encapsulation layer 510, the second encapsulation layer 510 is located on a side of the first encapsulation layer 400 away from the substrate 100. Optionally, the display panel further includes a third encapsulation layer 520, the third encapsulation layer 520 is located on a side of the second encapsulation layer 510 away from the substrate 100. By providing the third encapsulation layer 520, the sealing effect can be further improved. Optionally, the material of the second encapsulation layer 510 includes an organic material, which can improve the flatness on the second encapsulation layer 510. Optionally, the material of the third encapsulation layer 520 includes an inorganic material, to improve the density of the third encapsulation layer 520 and improve the encapsulation effect. Optionally, the material of the first encapsulation layer 400 includes an inorganic material, so that the encapsulation layer has good density and encapsulation effect.

In some optional embodiments, continue to refer to FIG. 1 to FIG. 5, the encapsulation portion 410 includes sub-encapsulation portions 410a for encapsulating the sub-units 310a, and at least two adjacent sub-encapsulation portions 410a are connected to each other. This ensures that there is no gap between the adjacent two sub-encapsulation portions 410a, improves the relative positional stability between the adjacent two sub-encapsulation portions 410a, improves the yield of the sub-encapsulation portions 410a. The adjacent two sub-encapsulation portions 410a can cover the isolation segment 220 located between the two sub-encapsulation portions 410a, improving the distribution area and encapsulation effect of the sub-encapsulation portions 410a.

The two connected sub-encapsulation portions 410a may be any sub-encapsulation portions 410a. In some optional embodiments, among the plurality of sub-encapsulation portions 410a corresponding to the same light-emitting unit 310, at least two adjacent sub-encapsulation portions 410a are connected to each other. The plurality of sub-encapsulation portions 410a corresponding to the same light-emitting unit 310 refer to the plurality of sub-encapsulation portions 410a configured to encapsulate the plurality of sub-units 310a in the same light-emitting unit 310.

In these optional embodiments, the same light-emitting unit 310 includes a plurality of sub-units 310a, each sub-unit 310a is correspondingly provided with a sub-encapsulation portion 410a, and the distances between the plurality of sub-units 310a corresponding to the same light-emitting unit 310 are relatively close. Therefore, in this embodiment, by connecting the sub-encapsulation portions 410a that are close to each other, the structure and preparation of the encapsulation portion 410 can be simplified.

Optionally, the plurality of sub-encapsulation portions 410a corresponding to the same light-emitting unit 310 are connected to each other to form an integral structure, i.e., the light-emitting unit 310 corresponds to one encapsulation portion 410, which can further simplify the structure of the encapsulation portion 410, so that all the isolation segments 220 corresponding to the same light-emitting unit 310 can be covered by the encapsulation portion 410, and all the isolation segments 220 within the same isolation opening 210 can be covered by the encapsulation portion 410, further increasing the distribution area of the encapsulation portion 410 and improving the encapsulation effect.

Optionally, the orthographic projection of the isolation segment 220 on the substrate 100 is located within the orthographic projection of the sub-encapsulation portion 410a on the substrate 100, to increase the distribution area of the encapsulation portion 410 and improve the encapsulation effect.

In some optional embodiments, referring to FIG. 1 and FIG. 2, a minimum distance between orthographic projections on the substrate 100 of the sub-openings 210a corresponding to two adjacent and connected sub-encapsulation portions 410a in the same light-emitting unit 310 is a first spacing d1, and a minimum distance between orthographic projections on the substrate 100 of two adjacent isolation openings 210 is a second spacing d2, and the first spacing d1 is less than the second spacing d2.

The orthographic projection of the sub-opening 210a on the substrate 100 is formed and surrounded by an orthographic projection of an inner wall surface of the isolation structure 200 facing the sub-opening 210a on the substrate 100. For example, the orthographic projection of the sub-opening 210a on the substrate 100 is formed and surrounded by an orthographic projection of an inner wall surface of the second sub-layer 202 of the isolation structure 200 facing the sub-opening 210a on the substrate 100. Similarly, the orthographic projection of the isolation opening 210 on the substrate 100 is formed and surrounded by an orthographic projection of an inner wall surface of the isolation structure 200 facing the isolation opening 210 on the substrate 100. For example, the orthographic projection of the isolation opening 210 on the substrate 100 is formed and surrounded by an orthographic projection of an inner wall surface of the second sub-layer 202 of the isolation structure 200 facing the isolation opening 210 on the substrate 100.

In these optional embodiments, the first spacing d1 is relatively small, making it easier for the adjacent sub-encapsulation portions 410a to connect at the position corresponding to the first spacing d1, simplifying the preparation process. Moreover, it makes the distance between adjacent sub-units 310a in the same light-emitting unit 310 smaller, ensuring the light-emitting effect of the light-emitting unit 310. The second spacing d2 is relatively large, which can improve the problem of light crosstalk between different light-emitting units 310 corresponding to the isolation openings 210.

Optionally, the first spacing d1 is a minimum spacing between two adjacent sub-encapsulation portions 410a in their side-by-side arrangement direction. For example, as two adjacent isolation openings 210 are arranged side-by-side along the first direction X, the first spacing d1 is the minimum spacing between the two adjacent sub-encapsulation portions 410a in the first direction X. Similarly, the second spacing d2 is a minimum spacing between two adjacent isolation openings 210 in their side-by-side arrangement direction. For example, as two adjacent isolation openings 210 are arranged side-by-side along the first direction X, the second spacing d2 is the minimum spacing between the two adjacent isolation openings 210 in the first direction X. In some embodiments of the present application, the two adjacent sub-encapsulation portions 410a and the two adjacent isolation openings 210 are arranged along a third direction P, and the third direction P intersects with the first direction X.

Optionally, a minimum distance between orthographic projections on the substrate 100 of the isolation openings 210 corresponding to two adjacent light-emitting units 310 of different colors is the second spacing d2. The second spacing d2 is relatively large, i.e., the spacing between the isolation openings 210 corresponding to light-emitting units 310 of different colors is relatively large, which can improve the problem of light crosstalk between light-emitting units 310 of different colors.

The plurality of isolation openings 210 are distributed in an array along the first direction X and the second direction Y. The plurality of isolation openings 210 may be arranged in various ways. Optionally, the plurality of isolation openings 210 include a first isolation opening 211, a second isolation opening 212, and a third isolation opening 213, and the plurality of light-emitting units 310 include a first light-emitting unit 311 corresponding to the first isolation opening 211, a second light-emitting unit 312 corresponding to the second isolation opening 212, and a third light-emitting unit 313 corresponding to the third isolation opening 213. The first light-emitting unit 311 corresponding to the first isolation opening 211 means that at least a portion of the first light-emitting unit 311 is located within the first isolation opening 211. Similarly, at least a portion of the second light-emitting unit 312 is located within the second isolation opening 212, and at least a portion of the third light-emitting unit 313 is located within the third isolation opening 213. The second spacing d2 may be a minimum spacing between adjacent first isolation opening 211 and second isolation opening 212, or the second spacing d2 may be a minimum spacing between adjacent first isolation opening 211 and third isolation opening 213, or the second spacing d2 may be a minimum spacing between adjacent second isolation opening 212 and third isolation opening 213.

Optionally, the isolation structure 200 further includes an isolation portion 230 located between two adjacent light-emitting units 310, the isolation portion 230 is correspondingly located between adjacent isolation openings 210, and a width of the isolation portion 230 is greater than a width of the isolation segment 220, so that the spacing between different light-emitting units 310 can be greater than the spacing between sub-units 310a within the light-emitting unit 310. The width of the isolation portion 230 can be understood as the minimum distance between two adjacent isolation openings 210.

In the embodiments of the present application, the isolation portion 230 is located between two adjacent isolation openings 210, and the isolation portion 230 is configured to define the isolation opening 210. The isolation segment 220 is located within the isolation opening 210, and the isolation segment 220 is configured to divide the isolation opening 210 into two or more sub-openings 210a. The width of the isolation portion 230 is greater than the width of the isolation segment 220, i.e., the distance between two adjacent isolation openings 210 is greater than the distance between two adjacent sub-openings 210a within the isolation opening 210, thereby making the spacing between adjacent light-emitting units 310 greater than the spacing between two adjacent sub-units 310a within the light-emitting unit 310, improving the light-emitting effect of the same light-emitting unit 310 while reducing light crosstalk between adjacent two light-emitting units 310.

Optionally, the isolation portion 230 may be located between adjacent first isolation opening 211 and second isolation opening 212, the isolation portion 230 may be located between adjacent first isolation opening 211 and third isolation opening 213, the isolation portion 230 may be located between adjacent second isolation opening 212 and third isolation opening 213.

A width direction of the isolation portion 230 refers to a direction from one of the two isolation openings 210 on both sides of the isolation portion 230 to the other, i.e., a side-by-side arrangement direction of the two isolation openings 210 on both sides of the isolation portion 230. A width direction of the isolation segment 220 refers to a direction from one of the two sub-openings 210a on both sides of the isolation segment 220 to the other, i.e., a side-by-side arrangement direction of the two sub-openings 210a on both sides of the isolation segment 220.

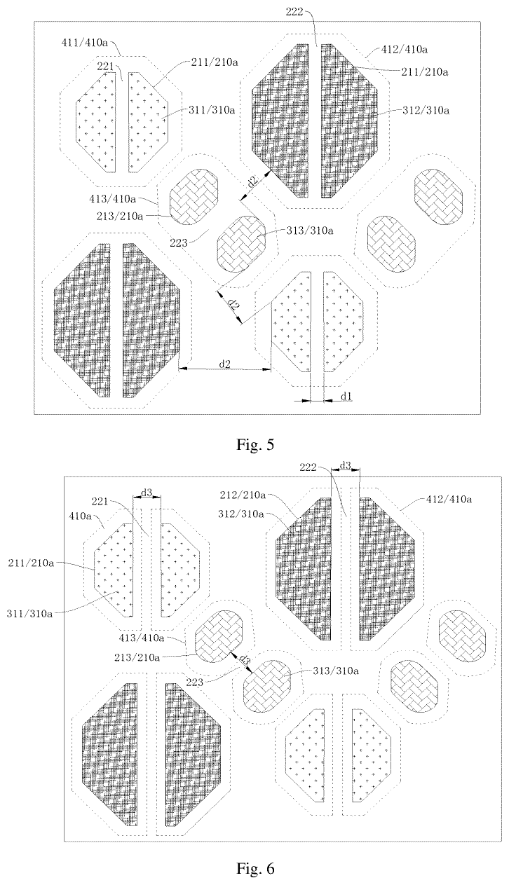

In some optional embodiments, referring to FIG. 5 and FIG. 6 together, orthographic projections on the substrate 100 of at least two adjacent sub-encapsulation portions 410a are disposed separately; a minimum distance between orthographic projections on the substrate 100 of the sub-openings 210a corresponding to two adjacent and spaced sub-encapsulation portions 410a in the same light-emitting unit 310 is a third spacing d3, a minimum distance between orthographic projections on the substrate 100 of two adjacent isolation openings 210 is a second spacing d2, and the third spacing d3 is less than the second spacing d2. Optionally, the third spacing d3 is the spacing between two adjacent sub-openings 210a in their side-by-side arrangement direction.

In these optional embodiments, the sub-encapsulation portions 410a corresponding to a portion of the sub-units 310a in the same light-emitting unit 310 are disposed separately, and the third spacing d3 is less than the second spacing d2, i.e., the distance between two adjacent sub-openings 210a corresponding to the same light-emitting unit 310 is less than the distance between two adjacent isolation openings 210, making the distance between the plurality of sub-units 310a corresponding to the same light-emitting unit 310 smaller and the spacing between different light-emitting units 310 larger, improving the light-emitting effect of the same light-emitting unit 310 while reducing light crosstalk between adjacent two light-emitting units 310.

And/or, a minimum distance between orthographic projections on the substrate 100 of the sub-openings 210a corresponding to two adjacent and connected sub-encapsulation portions 410a in the same light-emitting unit 310 is a first spacing d1, and the first spacing d1 is less than the third spacing d3.

In these optional embodiments, the first spacing d1 is relatively small, making it easy for the sub-encapsulation portions 410a to connect at this position, and the third spacing d3 is relatively large, making it easy for the adjacent sub-encapsulation portions 410a to be disposed separately at this position, which can simplify the preparation process difficulty.

In some optional embodiments, orthographic projections on the substrate 100 of the plurality of sub-encapsulation portions 410a corresponding to at least one light-emitting unit 310 are disposed separately. This allows the plurality of sub-units 310a corresponding to the plurality of light-emitting units 310 to be encapsulated independently. When the encapsulation of one sub-unit 310a fails, it will not affect the encapsulation effect of other sub-units 310a, further improving the yield of the display panel.

Optionally, as the first isolation opening 211 includes at least two sub-openings 210a and the encapsulation portions 410 corresponding to the at least two sub-openings 210a are disposed separately, the third spacing d3 may be the spacing between two adjacent sub-openings 210a in the first isolation opening 211. As the second isolation opening 212 includes at least two sub-openings 210a and the encapsulation portions 410 corresponding to the at least two sub-openings 210a are disposed separately, the third spacing d3 may be the spacing between two adjacent sub-openings 210a in the second isolation opening 212. As the third isolation opening 213 includes at least two sub-openings 210a and the encapsulation portions 410 corresponding to the at least two sub-openings 210a are disposed separately, the third spacing d3 may be the spacing between two adjacent sub-openings 210a in the third isolation opening 213.

In some optional embodiments, referring to the above, the isolation structure 200 includes an isolation portion 230 located between two adjacent isolation openings 210, and an orthographic projection on the substrate 100 of the isolation portion 230 located between two adjacent light-emitting units 310 with the same color is located within an orthographic projection on the substrate 100 of the encapsulation portion 410 corresponding to the two light-emitting units 310.

In these optional embodiments, the isolation portion 230 is covered by the encapsulation portion 410, which can further increase the distribution area and encapsulation effect of the encapsulation portion 410, thereby improving the yield of the display panel.

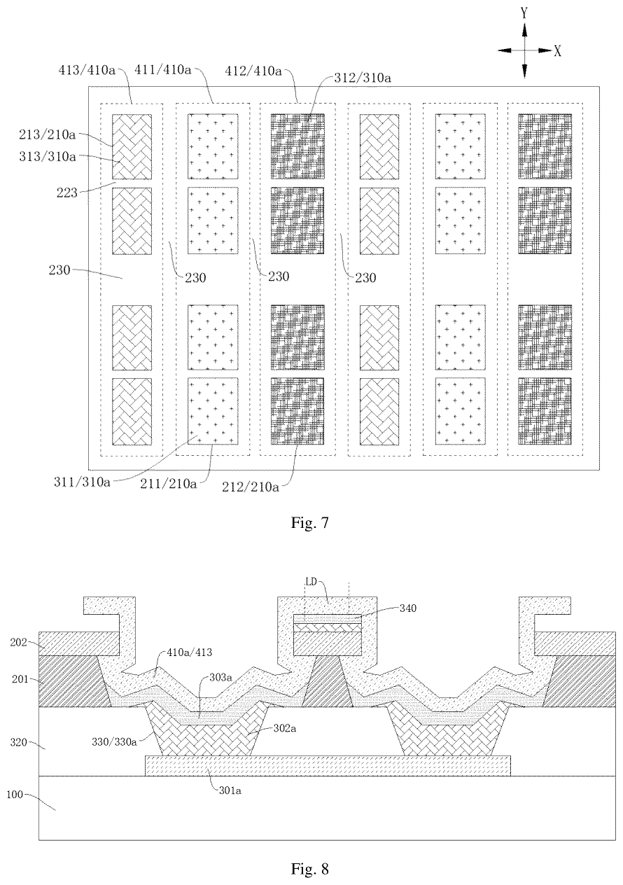

In some optional embodiments, as shown in FIG. 7, the encapsulation portions 410 corresponding to at least two adjacent light-emitting units 310 with the same light-emitting color are connected to each other. The light-emitting units 310 with the same light-emitting color and their corresponding encapsulation portions 410 can be formed in the same process step. By connecting the encapsulation portions 410 corresponding to at least two adjacent light-emitting units 310 with the same light-emitting color, the encapsulation portions 410 can be connected by retaining a portion of the encapsulation portion 410, thereby increasing the distribution area of the encapsulation portion 410 and simplifying the preparation process of the encapsulation portion 410.

In some optional embodiments, the plurality of sub-encapsulation portions 410a corresponding to at least two adjacent light-emitting units 310 with the same light-emitting color are connected to form an integral structure.

In these optional embodiments, at least two adjacent encapsulation portions 410 are connected to form an integral structure, which can improve the structural strength of the encapsulation portion 410, thereby improving the yield and sealing effect of the encapsulation portion 410.

In some optional embodiments, referring to FIG. 3 and FIG. 8 together, two adjacent sub-encapsulation portions 410a corresponding to one isolation opening 210 are connected to each other to form a continuous region LD, the continuous region LD is located on a side of the isolation segment 220 in the isolation opening 210 away from the substrate 100, and an orthographic projection of the continuous region LD on the substrate 100 is located within an orthographic projection of the isolation segment 220 on the substrate 100.

In these optional embodiments, as two adjacent sub-encapsulation portions 410a are connected to form an integral structure, a continuous region LD may be formed. The continuous region LD is correspondingly disposed on the isolation segment 220 between the two adjacent sub-openings 210a corresponding to the two adjacent sub-encapsulation portions 410a. The orthographic projection of the continuous region LD on the substrate 100 is located within the orthographic projection of the isolation segment 220 on the substrate 100, so that the isolation segment 220 can provide support for the continuous region LD.

Optionally, as shown in FIG. 3, the continuous region LD and the isolation segment 220 may be spaced apart from each other. Alternatively, as shown in FIG. 8, a redundant unit 340 may be disposed between the continuous region LD and the isolation segment 220. During the preparation of the light-emitting unit 310, part of the light-emitting material and/or the material of the second sub-electrode 303a is not etched away and remains between the continuous region LD and the isolation segment 220 to support the continuous region LD. Optionally, the redundant unit 340 includes two sub-layers, wherein the material of one sub-layer is the same as that of the light-emitting sub-structure 302a, and the material of the other sub-layer is the same as that of the second sub-electrode 303a.

In some optional embodiments, as shown in FIG. 1 to FIG. 7, the plurality of sub-openings 210a in the same isolation opening 210 have the same area of orthographic projection on the substrate 100. The same area of the plurality of sub-openings 210a allows the effective light-emitting areas of the plurality of sub-units 310a corresponding to the same light-emitting unit 310 to be the same.

Optionally, the plurality of sub-openings 210a in the same isolation opening 210 have the same shape of orthographic projection on the substrate 100. This can simplify the distribution pattern of the isolation structure 200 and facilitate the formation of the isolation structure 200.

Optionally, the two or more light-emitting sub-structures 302a corresponding to the same light-emitting unit 310 have the same area of orthographic projection on the substrate 100, allowing the effective light-emitting areas of the plurality of sub-units 310a corresponding to the same light-emitting unit 310 to be the same.

Optionally, the two or more light-emitting sub-structures 302a corresponding to the same light-emitting unit 310 have the same shape of orthographic projection on the substrate 100. This can simplify the distribution pattern of the light-emitting unit 310 and facilitate the formation of the isolation structure 200.

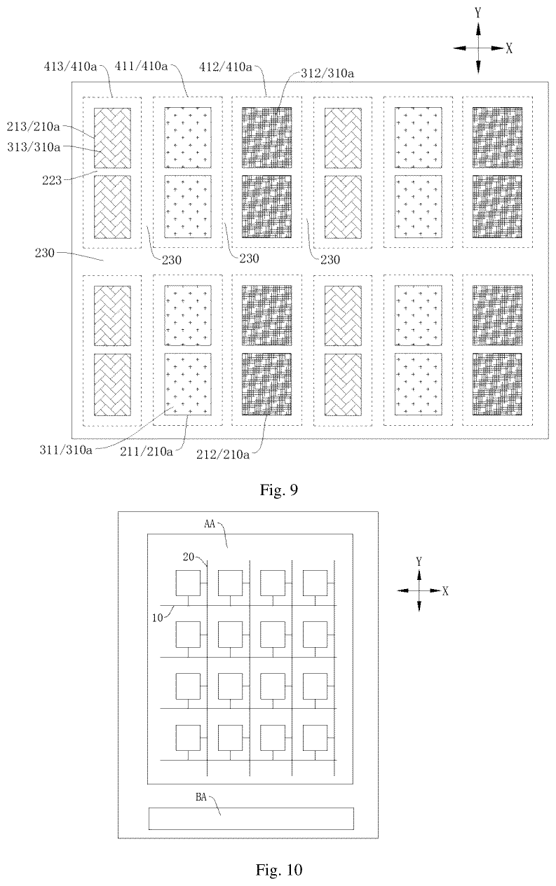

In some optional embodiments, as shown in FIG. 7 and FIG. 9, orthographic projections on the substrate 100 of at least two sub-openings 210a are polygonal, and long sides of the orthographic projections on the substrate 100 of the at least two sub-openings 210a extend along the same direction.

In these optional embodiments, the connection area between the isolation structure 200 and the second sub-electrode 303a is larger on the long side corresponding to the sub-opening 210a.

During the preparation of the second sub-electrode 303a, a linear evaporation source is usually configured to scan the display mother board. In the scanning direction, the deposition yield of the second sub-electrode 303a is better, and the connection yield between the second sub-electrode 303a and the isolation structure 200 is better. When the evaporation source is scanned in a direction perpendicular to the extension direction of the long side, by making the long sides of the orthographic projections on the substrate 100 of the at least two sub-openings 210a extend in the same direction, the connection yield between the second sub-electrode 303a on the long sides of the plurality of sub-openings 210a and the isolation structure 200 is improved, thereby improving the overall connection yield between the second sub-electrode 303a and the isolation structure 200.

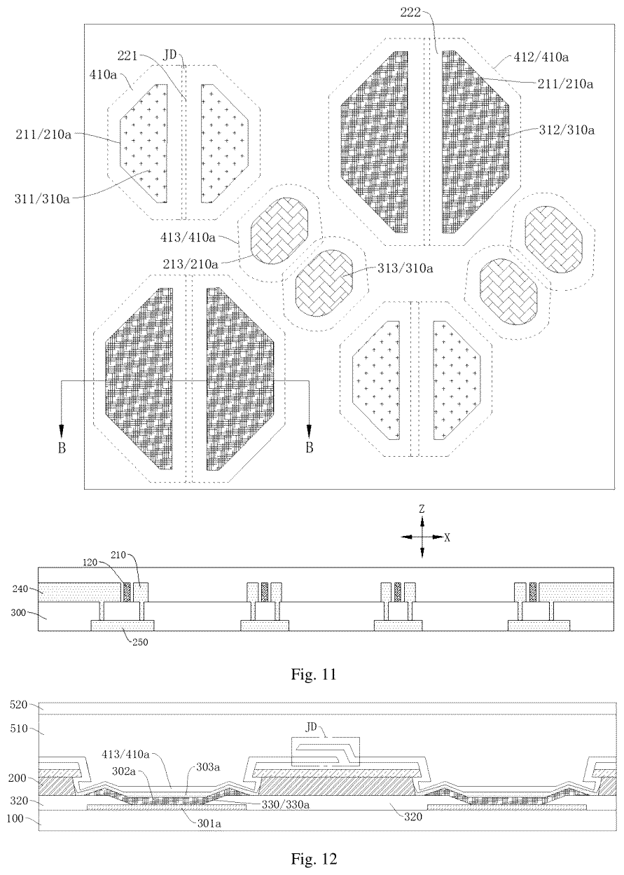

In some optional embodiments, as shown in FIG. 9 and FIG. 10, the display panel includes a scan signal line 10 extending along a preset direction, the long sides of the orthographic projections on the substrate 100 of the sub-openings 210a extend along the preset direction, or the long sides of the orthographic projections on the substrate 100 of the sub-openings 210a extend along a direction perpendicular to the preset direction. Optionally, the display panel further includes a data signal line 20, and an extension direction of the data signal line 20 is perpendicular to the preset direction. Optionally, the preset direction may be the first direction X, and the extension direction of the data signal line 20 may be the second direction Y.

In these optional embodiments, the above-mentioned scanning direction and the preset direction may be parallel or perpendicular. As the long sides corresponding to the sub-openings 210a extend along the preset direction, the scanning direction may be made perpendicular to the preset direction, thereby improving the connection yield between the second sub-electrode 303a and the isolation structure 200. As the long sides corresponding to the sub-openings 210a extend along a direction perpendicular to the preset direction, the scanning direction may be parallel to the preset direction, thereby improving the connection yield between the second sub-electrode 303a and the isolation structure 200.

In some optional embodiments, as shown in FIG. 9 and FIG. 10, the display panel includes a display area AA and a bonding area BA arranged along a preset direction, the long sides of the orthographic projections on the substrate 100 of the sub-openings 210a extend along the preset direction, or the long sides of the orthographic projections on the substrate 100 of the sub-openings 210a extend along a direction perpendicular to the preset direction. Optionally, the preset direction may be the first direction X or the second direction Y. This can also improve the connection yield between the second sub-electrode 303a and the isolation structure 200.

In other optional embodiments, as shown in FIG. 11 and FIG. 12, the encapsulation portion 410 includes sub-encapsulation portions 410a for encapsulating the sub-units 310a, orthographic projections on the substrate 100 of at least two adjacent sub-encapsulation portions 410a are partially overlapped to form an overlapping region JD, and the overlapping region JD is located within an orthographic projection of the isolation segment 220 on the substrate 100.

In these optional embodiments, by making two adjacent sub-encapsulation portions 410a overlap each other, the distribution area of the sub-encapsulation portions 410a can be further increased, thereby improving the encapsulation effect of the sub-encapsulation portions 410a. The two sub-encapsulation portions 410a overlap over the isolation segment 220, and the overlapping region JD is located within the orthographic projection of the isolation segment 220 on the substrate 100, so that the overlapping region JD is located on a side of the isolation segment 220 away from the substrate 100, to prevent the sub-encapsulation portion 410a from extending into the adjacent sub-opening 210a and affecting light emission.

Optionally, among the plurality of sub-encapsulation portions 410a corresponding to the same light-emitting unit 310, orthographic projections on the substrate 100 of at least two adjacent sub-encapsulation portions 410a are partially overlapped. This increases the distribution area of the plurality of sub-encapsulation portions 410a corresponding to the same light-emitting unit 310.

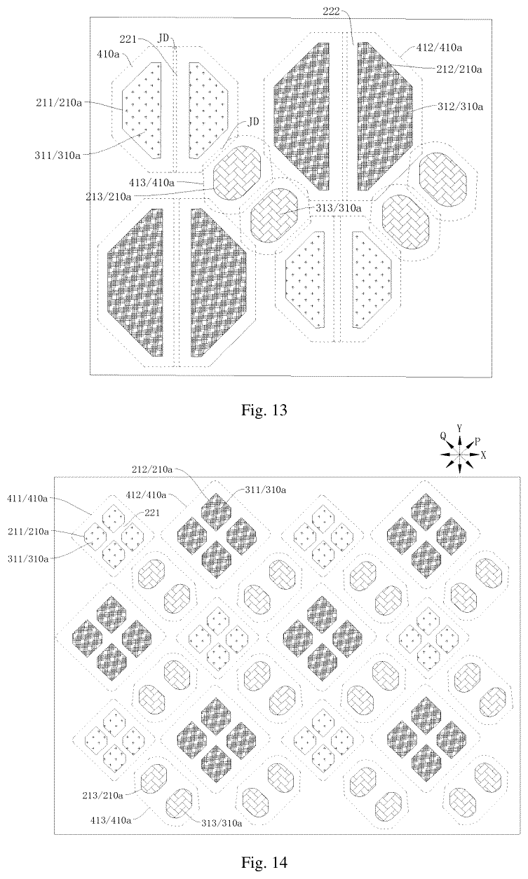

Optionally, as shown in FIG. 13, orthographic projections on the substrate 100 of the encapsulation portions 410 corresponding to at least two adjacent light-emitting units 310 with different light-emitting colors are partially overlapped. The light-emitting units 310 with different colors and their corresponding encapsulation portions 410 can be formed in different process steps. Therefore, by controlling the encapsulation portions 410 prepared in different process steps, the encapsulation portions 410 corresponding to at least two adjacent light-emitting units 310 with different light-emitting colors can be partially overlapped in the orthographic projection on the substrate 100.

In some optional embodiments, as shown in FIG. 2, the encapsulation portion 410 includes a first segment 401 and a second segment 402 connected to each other, the first segment 401 is located in the isolation opening 210, the second segment 402 is located on a side of the isolation structure 200 away from the substrate 100, and the orthographic projection of the second segment 402 on the substrate 100 has a first width W, wherein the first widths W of the second segments 402 of the encapsulation portion 410 corresponding to at least two light-emitting units 310 with different light-emitting colors are different, and/or the first widths W of the second segments 402 of the encapsulation portion 410 corresponding to at least two light-emitting units 310 with the same light-emitting color are the same.

The second segment 402 refers to a portion of the encapsulation portion 410 located on the side of the isolation structure 200 away from the substrate 100. The width of the second segment 402 can be understood as the extension dimension of the second segment 402 in a direction from the isolation opening 210 corresponding to the second segment 402 to an adjacent another isolation opening 210. The isolation opening 210 corresponding to the second segment 402 refers to the isolation opening 210 where the first segment 401 connected to the second segment 402 is located.

In these optional embodiments, the light-emitting units 310 with different colors and their corresponding encapsulation portions 410 can be formed in different process steps. When preparing the encapsulation portions 410 corresponding to light-emitting units 310 of different colors, the first widths W of the second segments 402 of the encapsulation portion 410 corresponding to light-emitting units 310 with different light-emitting colors may be different to simplify the preparation process. The light-emitting units 310 with the same color are formed in the same process step, therefore, and/or the first widths W of the second segments 402 of the encapsulation portion 410 corresponding to at least two light-emitting units 310 with the same light-emitting color are the same, making the light-emitting effects of the light-emitting units 310 with the same color more consistent.

Optionally, as the plurality of light-emitting units 310 include a first light-emitting unit 311, a second light-emitting unit 312, and a third light-emitting unit 313, the first width W includes a first sub-width W1 corresponding to the first light-emitting unit 311, a second sub-width W2 corresponding to the second light-emitting unit 312, and a third sub-width W3 corresponding to the third light-emitting unit 313. The first sub-widths W1 corresponding to the plurality of first light-emitting units 311 may be the same, the second sub-widths W2 corresponding to the plurality of second light-emitting units 312 may be the same, and the third sub-widths W3 corresponding to the plurality of third light-emitting units 313 may be the same. The first sub-width W1, the second sub-width W2, and the third sub-width W3 may be different.

Referring to the above, the plurality of isolation openings 210 include a first isolation opening 211, a second isolation opening 212, and a third isolation opening 213, and the plurality of light-emitting units 310 include a first light-emitting unit 311, a second light-emitting unit 312, and a third light-emitting unit 313. The first isolation opening 211, the second isolation opening 212, and the third isolation opening 213 may be arranged in various ways. For example, as shown in FIG. 1, FIG. 4 to FIG. 6, FIG. 11, FIG. 13 to FIG. 14, the first isolation opening 211 and the second isolation opening 212 are alternately arranged along a first direction X to form a first opening row, a plurality of third isolation openings 213 are sequentially arranged along the first direction X to form a second opening row, the first opening row and the second opening row are alternately arranged along a second direction Y, and the first direction X intersects with the second direction Y.

Optionally, referring to FIG. 1, an orthographic projection of the third isolation opening 213 on the substrate 100 is located within a virtual quadrilateral S1, centroids of orthographic projections of two of the first isolation openings 211 on the substrate 100 are located at two opposite corners of the virtual quadrilateral S1, centroids of orthographic projections of two of the second isolation openings 212 on the substrate 100 are located at the other two opposite corners of the virtual quadrilateral S1. The centroid can be understood as the geometric center of the pattern. The geometric center generally describes the most central position of an object with certain symmetry, such as the intersection of the two diagonals of a quadrilateral. For an object with a geometric center, during symmetric transformations that can coincide with itself, the rotation axis, symmetry axis, rotation base point, etc., must pass through the geometric center.

Optionally, as shown in FIG. 1, FIG. 4 to FIG. 6, FIG. 11, FIG. 13 to FIG. 14, as the first isolation opening 211, the second isolation opening 212, and the third isolation opening 213 are arranged in the above manner, at least one of the third isolation openings 213 includes two sub-openings 210a arranged along an extension direction of any diagonal L1 of the virtual quadrilateral S1.

In these optional embodiments, the four corners of the virtual quadrilateral S1 are provided with isolation openings 210, and the spacing along the first direction X and the second direction Y within the virtual quadrilateral S1 is relatively small. By dividing the third isolation opening 213 into two sub-openings 210a arranged along the extension direction of the diagonal L1, the distribution area of the three sub-openings 210a can be appropriately increased, thereby increasing the distribution area of the sub-units 310a and improving the effective light-emitting area.

The extension direction of the diagonal L1 intersects with the first direction X and the second direction Y. Optionally, an angle between the extension direction of the diagonal L1 and the first direction X and/or the second direction Y is 30 degrees to 50 degrees, for example, the angle between the extension direction of the diagonal L1 and the first direction X and/or the second direction Y is 30 degrees, 35 degrees, 40 degrees, 45 degrees, 48 degrees, 50 degrees, etc. As the angle between the extension direction of the diagonal L1 and the first direction X and/or the second direction Y is within the above range of 30 degrees to 50 degrees, it can prevent the distribution area of the sub-openings 210a from being affected by excessively large or small angles.

Optionally, as at least one of the third isolation openings 213 includes two sub-openings 210a arranged along the diagonal L1, at least one of the third light-emitting units 313 includes two sub-units 310a arranged along the extension direction of the diagonal L1, at least a portion of the sub-unit 310a of the third light-emitting unit 313 is located in the sub-opening 210a of the third isolation openings 213, the encapsulation portion 410 includes third sub-encapsulation portions 413 for encapsulating the sub-units 310a of the third light-emitting units 313, the isolation segments 220 include a third isolation segment 223 located in the third isolation opening 213, the third isolation segment 223 divides the third isolation opening 213 into a plurality of sub-openings 210a, and an orthographic projection of the third isolation segment 223 on the substrate 100 is located within an orthographic projection of the third sub-encapsulation portions 413 on the substrate 100.

In these optional embodiments, the third isolation segment 223 is disposed in the third isolation opening 213, and the third isolation segment 223 can divide the third isolation opening 213 into two sub-openings 210a. The orthographic projection of the third isolation segment 223 on the substrate 100 is located within the orthographic projection of the third sub-encapsulation portions 413 on the substrate 100, that is, the third sub-encapsulation portions 413 also cover the third isolation segment 223 located between adjacent sub-openings 210a, which can increase the distribution area of the third sub-encapsulation portions 413, improve the encapsulation effect, and thereby improve the yield and performance of the display panel.

Optionally, the plurality of third sub-encapsulation portions 413 corresponding to the same third light-emitting unit 313 are connected to each other. This ensures that there is no gap between the adjacent two third sub-encapsulation portions 413, improves the relative positional stability between the adjacent two third sub-encapsulation portions 413, improves the yield of the third sub-encapsulation portions 413. The adjacent two third sub-encapsulation portions 413 can cover the third isolation segment 223 located between the two third sub-encapsulation portions 413, improving the distribution area and encapsulation effect of the third sub-encapsulation portions 413.

In some optional embodiments, as shown in FIG. 4 to FIG. 5, at least one of the first isolation opening 211 and the second isolation opening 212 includes two sub-openings 210a arranged along the first direction X, and/or at least one of the first isolation opening 211 and the second isolation opening 212 includes two sub-openings 210a arranged along the second direction Y.

In these optional embodiments, the spacing between the first isolation opening 211 and the second isolation opening 212 adjacent along the first direction X and/or the second direction Y is relatively large. The first isolation opening 211 and/or the second isolation opening 212 may include two sub-openings 210a, and these two sub-openings 210a may be arranged along the first direction X or the second direction Y, which can appropriately increase the distribution area of the sub-openings 210a, thereby increasing the effective light-emitting area.

The embodiments of the present application are described by taking the example that both the first isolation opening 211 and the second isolation opening 212 include two sub-openings 210a. As the first isolation opening 211 includes two sub-openings 210a, the corresponding first light-emitting unit 311 includes two sub-units 310a. As the second isolation opening 212 includes two sub-openings 210a, the corresponding second light-emitting unit 312 includes two sub-units 310a.

Optionally, the first light-emitting unit 311 includes two sub-units 310a, the encapsulation portion 410 includes first sub-encapsulation portions 411 for encapsulating the sub-units 310a of the first light-emitting units 311, the isolation segments 220 include a first isolation segment 221 located in the first isolation opening 211, the first isolation segment 221 is configured to divide the first isolation opening 211 into two sub-openings 210a, and an orthographic projection of the first isolation segment 221 on the substrate 100 is located within an orthographic projection of the first sub-encapsulation portions 411 on the substrate 100.

In these optional embodiments, the orthographic projection of the first isolation segment 221 on the substrate 100 is located within the orthographic projection of the first sub-encapsulation portions 411 on the substrate 100, that is, the first sub-encapsulation portions 411 also cover the first isolation segment 221 located between adjacent sub-openings 210a, which can increase the distribution area of the first sub-encapsulation portions 411, improve the encapsulation effect, and thereby improve the yield and performance of the display panel.

Optionally, the two first sub-encapsulation portions 411 corresponding to the same first light-emitting unit 311 are connected to each other to form an integral structure. This ensures that there is no gap between the adjacent two first sub-encapsulation portions 411, improves the relative positional stability between the adjacent two first sub-encapsulation portions 411, improves the yield of the first sub-encapsulation portions 411. The adjacent two first sub-encapsulation portions 411 can cover the first isolation segment 221 located between the two first sub-encapsulation portions 411, improving the distribution area and encapsulation effect of the first sub-encapsulation portions 411.

Optionally, the second light-emitting unit 312 includes two sub-units 310a, the encapsulation portion 410 includes second sub-encapsulation portions 412 for encapsulating the sub-units 310a of the second light-emitting units 312, the isolation segments 220 include a second isolation segment 222 located in the second isolation opening 212, the second isolation segment 222 is configured to divide the second isolation opening 212 into two sub-openings 210a, and an orthographic projection of the second isolation segment 222 on the substrate 100 is located within an orthographic projection of the second sub-encapsulation portions 412 on the substrate 100.

In these optional embodiments, the orthographic projection of the second isolation segment 222 on the substrate 100 is located within the orthographic projection of the second sub-encapsulation portions 412 on the substrate 100, that is, the second sub-encapsulation portions 412 also cover the second isolation segment 222 located between adjacent sub-openings 210a, which can increase the distribution area of the second sub-encapsulation portions 412, improve the encapsulation effect, and thereby improve the yield and performance of the display panel.

Optionally, the two second sub-encapsulation portions 412 corresponding to the same second light-emitting unit 312 are connected to each other to form an integral structure. This ensures that there is no gap between the adjacent two second sub-encapsulation portions 412, improves the relative positional stability between the adjacent two second sub-encapsulation portions 412, improves the yield of the second sub-encapsulation portions 412. The adjacent two second sub-encapsulation portions 412 can cover the second isolation segment 222 located between the two second sub-encapsulation portions 412, improving the distribution area and encapsulation effect of the second sub-encapsulation portions 412.

In some optional embodiments, the two sub-openings 210a corresponding to the first isolation opening 211 are arranged along the first direction X, and the two sub-openings 210a corresponding to the second isolation opening 212 are arranged along the first direction X, i.e., the arrangement direction of the two sub-openings 210a corresponding to the first isolation opening 211 is the same as the arrangement direction of the two sub-openings 210a corresponding to the second isolation opening 212. This simplifies the distribution pattern of the sub-openings 210a of the plurality of isolation openings 210, and makes the light-emitting effect of the first light-emitting unit 311 tend to be consistent with that of the second light-emitting unit 312, improving the display effect of the display panel.

In some optional embodiments, as shown in FIG. 14, at least one of the first isolation opening 211 and the second isolation opening 212 includes four sub-openings 210a arranged in two rows and two columns along a third direction P and a fourth direction Q, and the first direction X, the second direction Y, the third direction P, and the fourth direction Q intersect in pairs and are in the same plane.

In these optional embodiments, the first isolation opening 211 and/or the second isolation opening 212 are divided into four sub-openings 210a, and the four sub-openings 210a are distributed in two rows and two columns, making the distribution of the four sub-openings 210a more regular and facilitating the distribution areas of the four sub-openings 210a to tend to be consistent.

Optionally, as the first isolation opening 211 and/or the second isolation opening 212 are divided into multiple sub-openings 210a in the above manner, at least one of the first light-emitting unit 311 and the second light-emitting unit 312 includes four sub-units 310a arranged in two rows and two columns along the third direction P and the fourth direction Q, so that the arrangement of the first light-emitting unit 311 matches the arrangement of the first isolation opening 211, and the arrangement of the second light-emitting unit 312 matches the arrangement of the second isolation opening 212.

Optionally, the first direction X is perpendicular to the second direction Y, so that the first isolation opening 211, the second isolation opening 212, and the third isolation opening 213 can be arranged in a horizontal and vertical manner, and the distribution of the plurality of isolation openings 210 is more uniform. The third direction P is perpendicular to the fourth direction Q, making the distribution of the plurality of sub-openings 210a more uniform. Optionally, an angle between the third direction P and the first direction X is 45 degrees, so that the distribution pattern of the plurality of sub-openings 210a matches the distribution pattern of the plurality of isolation openings 210.

Optionally, the first light-emitting unit 311 includes four sub-units 310a arranged in two rows and two columns along the third direction P and the fourth direction Q, the encapsulation portion 410 includes first sub-encapsulation portions 411 for encapsulating the sub-units 310a of the first light-emitting units 311, the isolation segments 220 include a first isolation segment 221 located in the first isolation opening 211, the first isolation segment 221 is configured to divide the first isolation opening 211 into four sub-openings 210a, and an orthographic projection of at least a portion of the first isolation segment 221 on the substrate 100 is located within an orthographic projection of the first sub-encapsulation portions 411 on the substrate 100.

In these optional embodiments, the orthographic projection of the first isolation segment 221 on the substrate 100 is located within the orthographic projection of the first sub-encapsulation portions 411 on the substrate 100, that is, the first sub-encapsulation portions 411 also cover the first isolation segment 221 located between adjacent sub-openings 210a, which can increase the distribution area of the first sub-encapsulation portions 411, improve the encapsulation effect, and thereby improve the yield and performance of the display panel.

Optionally, the two first sub-encapsulation portions 411 corresponding to the same first light-emitting unit 311 are connected to each other. For example, the four first sub-encapsulation portions 411 corresponding to the same first light-emitting unit 311 are connected to form an integral structure. This ensures that there is no gap between the adjacent two first sub-encapsulation portions 411, improves the relative positional stability between the adjacent two first sub-encapsulation portions 411, improves the yield of the first sub-encapsulation portions 411. The adjacent two first sub-encapsulation portions 411 can cover the first isolation segment 221 located between the two first sub-encapsulation portions 411, improving the distribution area and encapsulation effect of the first sub-encapsulation portions 411.

Optionally, the second light-emitting unit 312 includes four sub-units 310a arranged in two rows and two columns along the third direction P and the fourth direction Q, the encapsulation portion 410 includes second sub-encapsulation portions 412 for encapsulating the sub-units 310a of the second light-emitting units 312, the isolation segments 220 include a second isolation segment 222 located in the second isolation opening 212, the second isolation segment 222 is configured to divide the second isolation opening 212 into four sub-openings 210a, and an orthographic projection of at least a portion of the second isolation segment 222 on the substrate 100 is located within an orthographic projection of the second sub-encapsulation portions 412 on the substrate 100.

In these optional embodiments, the orthographic projection of the second isolation segment 222 on the substrate 100 is located within the orthographic projection of the second sub-encapsulation portions 412 on the substrate 100, that is, the second sub-encapsulation portions 412 also cover the second isolation segment 222 located between adjacent sub-openings 210a, which can increase the distribution area of the second sub-encapsulation portions 412, improve the encapsulation effect, and thereby improve the yield and performance of the display panel.

Optionally, the two second sub-encapsulation portions 412 corresponding to the same second light-emitting unit 312 are connected to each other. For example, the four second sub-encapsulation portions 412 corresponding to the same second light-emitting unit 312 are connected to form an integral structure. This ensures that there is no gap between the adjacent two second sub-encapsulation portions 412, improves the relative positional stability between the adjacent two second sub-encapsulation portions 412, improves the yield of the second sub-encapsulation portions 412. The adjacent two second sub-encapsulation portions 412 can cover the second isolation segment 222 located between the two second sub-encapsulation portions 412, improving the distribution area and encapsulation effect of the second sub-encapsulation portions 412.

In other optional embodiments, as shown in FIG. 7 and FIG. 9, a plurality of first isolation openings 211 are disposed separately along a second direction Y to form a first opening column, a plurality of second isolation openings 212 are disposed separately along the second direction Y to form a second opening column, a plurality of third isolation openings 213 are disposed separately along the second direction Y to form a third opening column. The first opening column, the second opening column, and the third opening column are sequentially and alternately arranged along a first direction X, and the first direction X intersects with the second direction Y. This method is simpler and easier to prepare.

As the plurality of isolation openings 210 are arranged in the above manner, at least one of the first isolation opening 211, the second isolation opening 212, and the third isolation opening 213 includes two or more sub-openings 210a disposed separately. That is, an isolation segment 220 may be provided in at least one of the first isolation opening 211, the second isolation opening 212, and the third isolation opening 213 to form sub-openings 210a.

Optionally, a dimension of the first isolation opening 211 in the second direction Y is greater than a dimension of the first isolation opening 211 in the first direction X, the first isolation opening 211 includes two or more sub-openings 210a arranged along the second direction Y, the first light-emitting unit 311 includes two or more sub-units 310a disposed separately along the second direction Y, the encapsulation portion 410 includes first sub-encapsulation portions 411 for encapsulating the sub-units 310a of the first light-emitting units 311, the isolation segments 220 include a first isolation segment 221 located in the first isolation opening 211, the first isolation segment 221 is configured to divide the first isolation opening 211 into two or more sub-openings 210a disposed separately along the second direction Y, and an orthographic projection of the first isolation segment 221 on the substrate 100 is located within an orthographic projection of the first sub-encapsulation portions 411 on the substrate 100.

In these optional embodiments, the extension length of the first isolation opening 211 in the second direction Y is relatively long, so the first isolation segment 221 divides the first isolation opening 211 into sub-openings 210a arranged along the second direction Y, which can reduce the difference in extension dimensions of the sub-openings 210a in the first direction X and the second direction Y. In addition, the orthographic projection of the first isolation segment 221 on the substrate 100 is located within the orthographic projection of the first sub-encapsulation portions 411 on the substrate 100, that is, the first sub-encapsulation portions 411 also cover the first isolation segment 221 located between adjacent sub-openings 210a, which can increase the distribution area of the first sub-encapsulation portions 411, improve the encapsulation effect, and thereby improve the yield and performance of the display panel.

Optionally, the first isolation segment 221 may extend along the first direction X, so that the first isolation segment 221 can divide the first isolation opening 211 into two or more sub-openings 210a spaced along the second direction Y.

Optionally, the two first sub-encapsulation portions 411 corresponding to the same first light-emitting unit 311 are connected to each other. This ensures that there is no gap between the adjacent two first sub-encapsulation portions 411, improves the relative positional stability between the adjacent two first sub-encapsulation portions 411, improves the yield of the first sub-encapsulation portions 411. The adjacent two first sub-encapsulation portions 411 can cover the first isolation segment 221 located between the two first sub-encapsulation portions 411, improving the distribution area and encapsulation effect of the first sub-encapsulation portions 411.

Optionally, a dimension of the second isolation opening 212 in the second direction Y is greater than a dimension of the second isolation opening 212 in the first direction X, the second isolation opening 212 includes two or more sub-openings 210a arranged along the second direction Y, the second light-emitting unit 312 includes two or more sub-units 310a disposed separately along the second direction Y, the encapsulation portion 410 includes second sub-encapsulation portions 412 for encapsulating the sub-units 310a of the second light-emitting units 312, the isolation segments 220 include a second isolation segment 222 located in the second isolation opening 212, the second isolation segment 222 is configured to divide the second isolation opening 212 into two or more sub-openings 210a disposed separately along the second direction Y, and an orthographic projection of the second isolation segment 222 on the substrate 100 is located within an orthographic projection of the second sub-encapsulation portions 412 on the substrate 100.

In these optional embodiments, the extension length of the second isolation opening 212 in the second direction Y is relatively long, so the second isolation segment 222 divides the second isolation opening 212 into sub-openings 210a arranged along the second direction Y, which can reduce the difference in extension dimensions of the sub-openings 210a in the first direction X and the second direction Y. In addition, the orthographic projection of the second isolation segment 222 on the substrate 100 is located within the orthographic projection of the second sub-encapsulation portions 412 on the substrate 100, that is, the second sub-encapsulation portions 412 also cover the second isolation segment 222 located between adjacent sub-openings 210a, which can increase the distribution area of the second sub-encapsulation portions 412, improve the encapsulation effect, and thereby improve the yield and performance of the display panel.

Optionally, the second isolation segment 222 may extend along the first direction X, so that the second isolation segment 222 can divide the second isolation opening 212 into two or more sub-openings 210a spaced along the second direction Y.

Optionally, the two second sub-encapsulation portions 412 corresponding to the same second light-emitting unit 312 are connected to each other. This ensures that there is no gap between the adjacent two second sub-encapsulation portions 412, improves the relative positional stability between the adjacent two second sub-encapsulation portions 412, improves the yield of the second sub-encapsulation portions 412. The adjacent two second sub-encapsulation portions 412 can cover the second isolation segment 222 located between the two second sub-encapsulation portions 412, improving the distribution area and encapsulation effect of the second sub-encapsulation portions 412.

Optionally, a dimension of the third isolation opening 213 in the second direction Y is greater than a dimension of the third isolation opening 213 in the first direction X, the third isolation opening 213 includes two or more sub-openings 210a arranged along the second direction Y, the third light-emitting unit 313 includes two or more sub-units 310a disposed separately along the second direction Y, the encapsulation portion 410 includes third sub-encapsulation portions 413 for encapsulating the sub-units 310a of the third light-emitting units 313, the isolation segments 220 include a third isolation segment 223 located in the third isolation opening 213, the third isolation segment 223 is configured to divide the third isolation opening 213 into two or more sub-openings 210a disposed separately along the second direction Y, and an orthographic projection of the third isolation segment 223 on the substrate 100 is located within an orthographic projection of the third sub-encapsulation portions 413 on the substrate 100.

In these optional embodiments, the extension length of the third isolation opening 213 in the second direction Y is relatively long, so the third isolation segment 223 divides the third isolation opening 213 into sub-openings 210a arranged along the second direction Y, which can reduce the difference in extension dimensions of the sub-openings 210a in the first direction X and the second direction Y. In addition, the orthographic projection of the third isolation segment 223 on the substrate 100 is located within the orthographic projection of the third sub-encapsulation portions 413 on the substrate 100, that is, the third sub-encapsulation portions 413 also cover the third isolation segment 223 located between adjacent sub-openings 210a, which can increase the distribution area of the third sub-encapsulation portions 413, improve the encapsulation effect, and thereby improve the yield and performance of the display panel.

Optionally, the third isolation segment 223 may extend along the first direction X, so that the third isolation segment 223 can divide the third isolation opening 213 into two or more sub-openings 210a spaced along the second direction Y.

Optionally, the two third sub-encapsulation portions 413 corresponding to the same third light-emitting unit 313 are connected to each other. This ensures that there is no gap between the adjacent two third sub-encapsulation portions 413, improves the relative positional stability between the adjacent two third sub-encapsulation portions 413, improves the yield of the third sub-encapsulation portions 413. The adjacent two third sub-encapsulation portions 413 can cover the third isolation segment 223 located between the two third sub-encapsulation portions 413, improving the distribution area and encapsulation effect of the third sub-encapsulation portions 413.

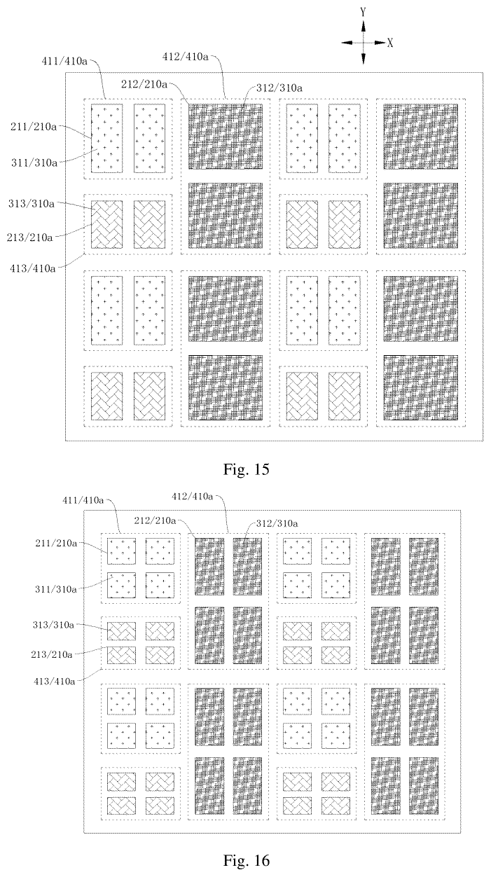

In still other optional embodiments, as shown in FIG. 15 and FIG. 16, the first isolation opening 211 and the third isolation opening 213 are alternately arranged along a second direction Y to form a fourth opening column, a plurality of second isolation openings 212 are sequentially arranged along the second direction Y to form a fifth opening column, the fourth opening column and the fifth opening column are alternately arranged along a first direction X, one of the first isolation openings 211 and one of the third isolation openings 213 in the fourth opening column are arranged along the first direction X with the same second isolation opening 212 in the fifth opening column, and the first direction X intersects with the second direction Y. As the plurality of isolation openings 210 are arranged in the above manner, the spacing between the first isolation opening 211, the second isolation opening 212, and the third isolation opening 213 can be reduced, thereby reducing the spacing between the first light-emitting unit 311, the second light-emitting unit 312, and the third light-emitting unit 313, to improve the display effect.

Optionally, at least one of the first isolation opening 211, the second isolation opening 212, and the third isolation opening 213 includes two or more sub-openings 210a disposed separately; that is, an isolation segment 220 may be provided in at least one of the first isolation opening 211, the second isolation opening 212, and the third isolation opening 213 to form sub-openings 210a.

Optionally, the second isolation opening 212 includes two or more sub-openings 210a disposed separately along the second direction Y. Since the second isolation opening 212 needs to correspond to the first isolation opening 211 and the third isolation opening 213, the extension dimension of the second isolation opening 212 in the second direction Y is relatively long. By dividing the second isolation opening 212 into two sub-openings 210a distributed along the second direction Y, the difference in dimensions of each sub-opening 210a in the first direction X and the second direction Y is reduced.

Alternatively, the second isolation opening 212 includes four sub-openings 210a arranged in two rows and two columns along the first direction X and the second direction Y. This makes the shape of the divided sub-openings 210a close to that of the second isolation opening 212.

Optionally, the dimension of the second isolation opening 212 in the second direction Y is greater than its dimension in the first direction X, so that the second isolation opening 212 can correspond to the first isolation opening 211 and the third isolation opening 213.

Optionally, as shown in FIG. 15, the first isolation opening 211 and/or the third isolation opening 213 include two or more sub-openings 210a disposed separately along the first direction X. This makes the sub-openings 210a divided from the first isolation opening 211 and/or the third isolation opening 213 have a longer dimension in the second direction Y, which is the same as the long-side extension direction of the second isolation opening 212, and can improve the connection yield between the second sub-electrode 303a and the isolation structure 200.

Alternatively, as shown in FIG. 16, the first isolation opening 211 and/or the third isolation opening 213 include four sub-openings 210a arranged in two rows and two columns along the first direction X and the second direction Y. This makes the sub-openings 210a divided from the first isolation opening 211 and/or the third isolation opening 213 close to their own shape.

Optionally, the first light-emitting unit 311 includes a plurality of sub-units 310a, the encapsulation portion 410 includes first sub-encapsulation portions 411 for encapsulating the sub-units 310a of the first light-emitting units 311, the isolation segments 220 include a first isolation segment 221 located in the first isolation opening 211, the first isolation segment 221 is configured to divide the first isolation opening 211 into a plurality of sub-openings 210a, and an orthographic projection of the first isolation segment 221 on the substrate 100 is located within an orthographic projection of the first sub-encapsulation portions 411 on the substrate 100.

In these optional embodiments, the orthographic projection of the first isolation segment 221 on the substrate 100 is located within the orthographic projection of the first sub-encapsulation portions 411 on the substrate 100, that is, the first sub-encapsulation portions 411 also cover the first isolation segment 221 located between adjacent sub-openings 210a, which can increase the distribution area of the first sub-encapsulation portions 411, improve the encapsulation effect, and thereby improve the yield and performance of the display panel.

Optionally, the two first sub-encapsulation portions 411 corresponding to the same first light-emitting unit 311 are connected to each other. This ensures that there is no gap between the adjacent two first sub-encapsulation portions 411, improves the relative positional stability between the adjacent two first sub-encapsulation portions 411, improves the yield of the first sub-encapsulation portions 411. The adjacent two first sub-encapsulation portions 411 can cover the first isolation segment 221 located between the two first sub-encapsulation portions 411, improving the distribution area and encapsulation effect of the first sub-encapsulation portions 411.

Optionally, the second light-emitting unit 312 includes a plurality of sub-units 310a, the encapsulation portion 410 includes second sub-encapsulation portions 412 for encapsulating the sub-units 310a of the second light-emitting units 312, the isolation segments 220 include a second isolation segment 222 located in the second isolation opening 212, the second isolation segment 222 is configured to divide the second isolation opening 212 into a plurality of sub-openings 210a, and an orthographic projection of the second isolation segment 222 on the substrate 100 is located within an orthographic projection of the second sub-encapsulation portions 412 on the substrate 100.

In these optional embodiments, the orthographic projection of the second isolation segment 222 on the substrate 100 is located within the orthographic projection of the second sub-encapsulation portions 412 on the substrate 100, that is, the second sub-encapsulation portions 412 also cover the second isolation segment 222 located between adjacent sub-openings 210a, which can increase the distribution area of the second sub-encapsulation portions 412, improve the encapsulation effect, and thereby improve the yield and performance of the display panel.

Optionally, the two second sub-encapsulation portions 412 corresponding to the same second light-emitting unit 312 are connected to each other. This ensures that there is no gap between the adjacent two second sub-encapsulation portions 412, improves the relative positional stability between the adjacent two second sub-encapsulation portions 412, improves the yield of the second sub-encapsulation portions 412. The adjacent two second sub-encapsulation portions 412 can cover the second isolation segment 222 located between the two second sub-encapsulation portions 412, improving the distribution area and encapsulation effect of the second sub-encapsulation portions 412.

Optionally, the third light-emitting unit 313 includes a plurality of sub-units 310a, the encapsulation portion 410 includes third sub-encapsulation portions 413 for encapsulating the sub-units 310a of the third light-emitting units 313, the isolation segments 220 include a third isolation segment 223 located in the third isolation opening 213, the third isolation segment 223 is configured to divide the third isolation opening 213 into a plurality of sub-openings 210a, and an orthographic projection of the third isolation segment 223 on the substrate 100 is located within an orthographic projection of the third sub-encapsulation portions 413 on the substrate 100.

In these optional embodiments, the orthographic projection of the third isolation segment 223 on the substrate 100 is located within the orthographic projection of the third sub-encapsulation portions 413 on the substrate 100, that is, the third sub-encapsulation portions 413 also cover the third isolation segment 223 located between adjacent sub-openings 210a, which can increase the distribution area of the third sub-encapsulation portions 413, improve the encapsulation effect, and thereby improve the yield and performance of the display panel.

Optionally, the two third sub-encapsulation portions 413 corresponding to the same third light-emitting unit 313 are connected to each other. This ensures that there is no gap between the adjacent two third sub-encapsulation portions 413, improves the relative positional stability between the adjacent two third sub-encapsulation portions 413, improves the yield of the third sub-encapsulation portions 413. The adjacent two third sub-encapsulation portions 413 can cover the third isolation segment 223 located between the two third sub-encapsulation portions 413, improving the distribution area and encapsulation effect of the third sub-encapsulation portions 413.

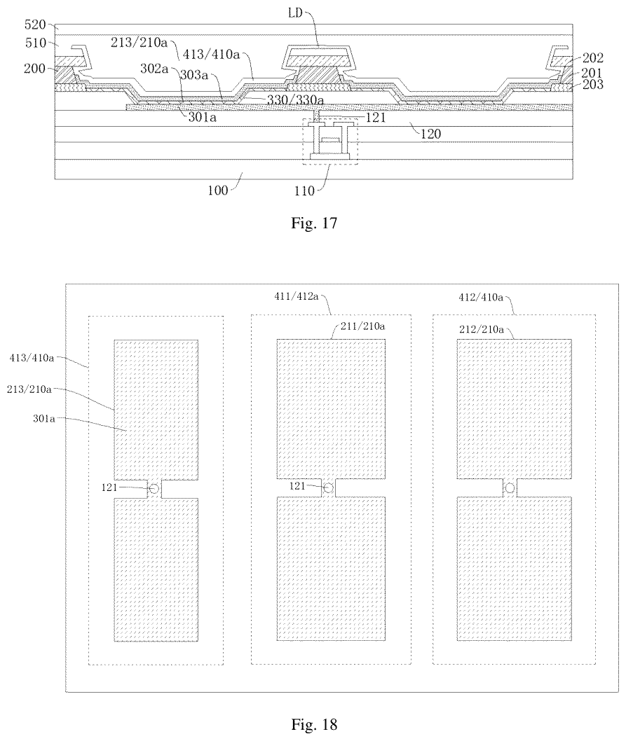

In some optional embodiments, the isolation structure 200 may only include the aforementioned first sub-layer 201 and second sub-layer 202, and the second sub-electrode 303a is electrically connected to the first sub-layer 201. In other optional embodiments, as shown in FIG. 17, the isolation structure 200 includes a third sub-layer 203, a first sub-layer 201, and a second sub-layer 202 sequentially arranged in a direction away from the substrate 100, an orthographic projection of the first sub-layer 201 on the substrate 100 is located within an orthographic projection of the second sub-layer 202 on the substrate 100, the third sub-layer 203 includes a conductive material, and the second sub-electrode 303a is electrically connected with the third sub-layer 203. Optionally, the second sub-electrode 303a may also be electrically connected with the first sub-layer 201. The second sub-electrode 303a is electrically connected with the third sub-layer 203 or the first sub-layer 201, so that the plurality of second sub-electrodes 303a can be interconnected as a surface electrode through the isolation structure 200.

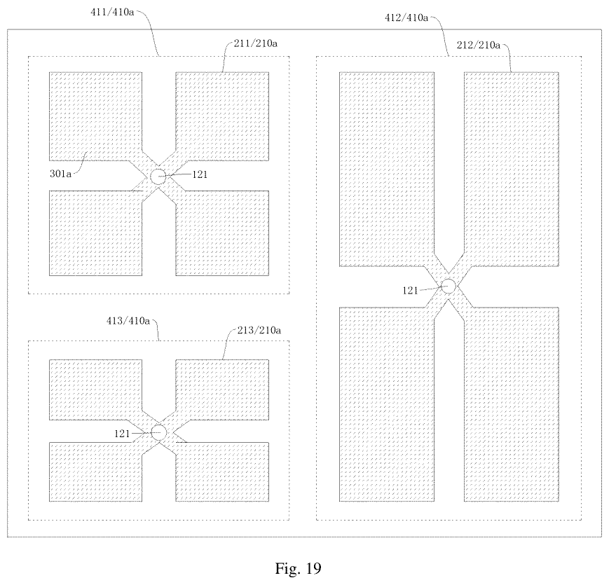

In some optional embodiments, as shown in FIG. 17 to FIG. 19, the display panel further includes: a pixel circuit 110, disposed on one side of the substrate 100; a first insulation layer 120, located on one side of the pixel circuit 110 away from the substrate 100, wherein the first sub-electrode 301a is located on one side of the first insulation layer 120 away from the substrate 100, the first insulation layer 120 is provided with a connection via 121, and a plurality of first sub-electrodes 301a corresponding to the same light-emitting unit 310 are electrically connected through the same pixel circuit 110 and the same connection via 121.

In these optional embodiments, the plurality of first sub-electrodes 301a are electrically connected through the same connection via 121 and the same pixel circuit 110, enabling the same pixel circuit 110 to drive the plurality of sub-units 310a. The same connection via 121 corresponds to the plurality of first sub-electrodes 301a, which can simplify the preparation of the first insulation layer 120.

Optionally, the first insulation layer 120 may be a planarization layer.

Optionally, as the isolation opening 210 includes two sub-openings 210a disposed separately, an orthographic projection of the connection via 121 on the substrate 100 is located between orthographic projections of the light-emitting sub-structures 302a of two adjacent sub-openings 210a on the substrate 100. This makes the distances from the respective first sub-electrodes 301a to the connection via 121 tend to be consistent, reducing the difference in light-emitting effects between different sub-units 310a.

Alternatively, the isolation opening 210 includes four sub-openings 210a arranged in two rows and two columns, and an orthographic projection of the connection via 121 on the substrate 100 is located at the middle of orthographic projections of four of the sub-units 310a on the substrate 100. This makes the distances from the respective first sub-electrodes 301a to the connection via 121 tend to be consistent, reducing the difference in light-emitting effects between different sub-units 310a.

As shown in FIG. 1 to FIG. 19, a second aspect of embodiments of the present application further provides a display panel, including: a substrate 100; an isolation structure 200, located on one side of the substrate 100, wherein the isolation structure 200 defines and forms an isolation opening 210; a light-emitting layer 300, located on one side of the substrate 100, wherein the light-emitting layer 300 includes light-emitting units 310, at least a portion of the light-emitting unit 310 is located within the isolation opening 210, at least one of the light-emitting units 310 includes two or more sub-units 310a disposed separately, the sub-units 310a include a first sub-electrode 301a, a light-emitting sub-structure 302a, and a second sub-electrode 303a sequentially stacked in a direction away from the substrate 100; and a first encapsulation layer 400, including an encapsulation portion 410 for encapsulating the light-emitting units 310, the encapsulation portion 410 including sub-encapsulation portions 410a for encapsulating the sub-units 310a, wherein the first sub-electrodes 301a of a plurality of sub-units 310a in the same light-emitting unit 310 are electrically connected to each other, the isolation structure 200 includes an isolation segment 220, an orthographic projection of the isolation segment 220 on the substrate 100 is located between orthographic projections of adjacent two sub-units 310a on the substrate 100, and the orthographic projection of the isolation segment 220 on the substrate 100 is located within an orthographic projection of the encapsulation portion 410 on the substrate 100.

In the display panel provided by the embodiments of the present application, the display panel includes a substrate 100, an isolation structure 200, a light-emitting layer 300, and a first encapsulation layer 400. At least a portion of the light-emitting unit 310 of the light-emitting layer 300 is located within the isolation opening 210. The light-emitting units 310 include two or more sub-units 310a disposed separately, the sub-units 310a include a first sub-electrode 301a, a light-emitting sub-structure 302a, and a second sub-electrode 303a, wherein the first sub-electrode 301a and the second sub-electrode 303a are configured to drive the light-emitting sub-structure 302a to emit light. The encapsulation portion 410 of the first encapsulation layer 400 provides encapsulation protection for the light-emitting units 310. The first sub-electrodes 301a of the plurality of sub-units 310a in the same light-emitting unit 310 are electrically connected to each other, enabling the plurality of sub-units 310a of the same light-emitting unit 310 to be driven by the same pixel circuit 110, which can simplify the structure of the pixel circuit 110. The orthographic projection of the isolation segment 220 on the substrate 100 is located within the orthographic projection of the encapsulation portion 410 on the substrate 100, that is, the encapsulation portion 410 also covers the isolation segment 220 located between adjacent sub-units 310a, which can increase the distribution area of the encapsulation portion 410, improve the encapsulation effect, and thereby improve the yield and performance of the display panel.

The display panel of this embodiment may cross-reference any of the above embodiments. For example, the arrangement of the isolation opening 210, the isolation segment 220, and the encapsulation portion 410 may be referred to the above, and will not be repeated here.

As shown in FIG. 1 to FIG. 19, a second aspect of embodiments of the present application further provides a display panel, including: a substrate 100; an isolation structure 200, located on one side of the substrate 100, wherein the isolation structure 200 defines and forms an isolation opening 210, the isolation structure 200 includes an isolation segment 220, the isolation segment 220 is disposed within at least one isolation opening 210 and divides the isolation opening 210 into at least two sub-openings 210a; a light-emitting layer 300, located on one side of the substrate 100, wherein the light-emitting layer 300 includes light-emitting units 310, at least a portion of the light-emitting unit 310 is located within the isolation opening 210, at least one of the light-emitting units 310 includes two or more sub-units 310a disposed separately, at least a portion of the sub-unit 310a is located within the sub-opening 210a, the sub-units 310a include a first sub-electrode 301a, a light-emitting sub-structure 302a, and a second sub-electrode 303a sequentially stacked in a direction away from the substrate 100; and a first encapsulation layer 400, including an encapsulation portion 410 for encapsulating the light-emitting units 310, the encapsulation portion 410 including sub-encapsulation portions 410a for encapsulating the sub-units 310a, wherein the first sub-electrodes 301a of a plurality of sub-units 310a in the same light-emitting unit 310 are electrically connected to each other, and an orthographic projection of the isolation segment 220 on the substrate 100 is partially overlapped with an orthographic projection of the sub-encapsulation portion 410a on the substrate 100.

In the display panel provided by the embodiments of the present application, the display panel includes a substrate 100, an isolation structure 200, a light-emitting layer 300, and a first encapsulation layer 400. At least a portion of the light-emitting unit 310 of the light-emitting layer 300 is located within the isolation opening 210. The light-emitting units 310 include two or more sub-units 310a disposed separately, the sub-units 310a include a first sub-electrode 301a, a light-emitting sub-structure 302a, and a second sub-electrode 303a, wherein the first sub-electrode 301a and the second sub-electrode 303a are configured to drive the light-emitting sub-structure 302a to emit light. The encapsulation portion 410 of the first encapsulation layer 400 provides encapsulation protection for the light-emitting units 310. The first sub-electrodes 301a of the plurality of sub-units 310a in the same light-emitting unit 310 are electrically connected to each other, enabling the plurality of sub-units 310a of the same light-emitting unit 310 to be driven by the same pixel circuit 110, which can simplify the structure of the pixel circuit 110. The orthographic projection of the isolation segment 220 on the substrate 100 is partially overlapped with the orthographic projection of the sub-encapsulation portion 410a on the substrate 100, that is, a portion of the isolation segments 220 may be exposed by the sub-encapsulation portion 410a, and there are gaps between some adjacent sub-encapsulation portions 410a, which prevents the transmission of encapsulation defects on the encapsulation layer and improves the yield of the display panel.

Optionally, as shown in FIG. 6, orthographic projections on the substrate 100 of at least two adjacent sub-encapsulation portions 410a are disposed separately, so that the encapsulation of each sub-unit 310a is independent. Optionally, among the plurality of sub-encapsulation portions 410a corresponding to the same light-emitting unit 310, orthographic projections on the substrate 100 of adjacent two sub-encapsulation portions 410a are disposed separately. This makes it difficult for encapsulation defects to transmit in the encapsulation portion 410 corresponding to the same light-emitting unit 310, improving the encapsulation effect of a single light-emitting unit 310.

The display panel of this embodiment may cross-reference any of the above embodiments. For example, the arrangement of the isolation opening 210 and the encapsulation portion 410 may be referred to the above, and will not be repeated here.

A second aspect of embodiments of the present application further provides a display device, including the display panel according to any of the above first aspect embodiments. Since the display device provided by the second aspect embodiments of the present application includes the display panel according to any of the first aspect embodiments, the display device provided by the second aspect embodiments of the present application has the beneficial effects of the display panel according to any of the first aspect embodiments, which will not be repeated here.

The display device in the embodiments of the present application includes but is not limited to mobile phones, personal digital assistants (PDA), tablet computers, e-books, televisions, access control systems, smart fixed-line telephones, control consoles, and other devices with display functions.

According to the embodiments of the present application as described above, these embodiments do not describe all details in detail, nor limit the invention to the specific embodiments. Obviously, many modifications and changes can be made according to the above description. This specification selects and specifically describes these embodiments to better explain the principles and practical applications of the present application, so that those skilled in the art can well utilize the present application and modifications based on the present application. The present application is only limited by the claims and their full scope and equivalents.

What is claimed is:

1. A display panel, comprising:
a substrate;
an isolation structure located on one side of the substrate, wherein the isolation structure defines an isolation opening, the isolation structure comprises an isolation segment, the isolation segment is disposed within at least one isolation opening and divides the isolation opening into at least two sub-openings;
a light-emitting layer located on one side of the substrate, wherein the light-emitting layer comprises a plurality of light-emitting units, at least a portion of the light-emitting unit is located within the isolation opening, at least one of the plurality of light-emitting units comprises at least two sub-units disposed separately, at least a portion of the sub-unit is located within the sub-opening, each of the sub-units comprises a first sub-electrode, a light-emitting sub-structure, and a second sub-electrode sequentially stacked in a direction away from the substrate; and
a first encapsulation layer comprising an encapsulation portion for encapsulating the light-emitting units;
wherein the first sub-electrodes of a plurality of sub-units in the same light-emitting unit are electrically connected to each other, and an orthographic projection of at least a portion of the isolation segment on the substrate is located within an orthographic projection of the encapsulation portion on the substrate.

2. The display panel of claim 1, wherein the encapsulation portion comprises sub-encapsulation portions for encapsulating the sub-units, and at least two adjacent sub-encapsulation portions are connected to each other.

3. The display panel of claim 2, wherein the isolation segment has an orthographic projection on the substrate located within an orthographic projection of the sub-encapsulation portion on the substrate;
at least two adjacent sub-encapsulation portions of a plurality of sub-encapsulation portions corresponding to the same light-emitting unit are connected to each other; or
a plurality of sub-encapsulation portions corresponding to the same light-emitting unit are connected to form an integral structure.

4. The display panel of claim 2, wherein a minimum distance between orthographic projections on the substrate of the sub-openings corresponding to two adjacent and connected sub-encapsulation portions in the same light-emitting unit is a first spacing, and a minimum distance between orthographic projections on the substrate of two adjacent isolation openings is a second spacing, and the first spacing is less than the second spacing.

5. The display panel of claim 4, wherein a minimum distance between orthographic projections on the substrate of the isolation openings corresponding to two adjacent light-emitting units of different colors is the second spacing; or
the isolation structure further comprises an isolation portion located between two adjacent light-emitting units, and a width of the isolation portion is greater than a width of the isolation segment.

6. The display panel of claim 2, wherein orthographic projections on the substrate of at least two adjacent sub-encapsulation portions are disposed separately; a minimum distance between orthographic projections on the substrate of the sub-openings corresponding to two adjacent and spaced sub-encapsulation portions in the same light-emitting unit is a third spacing,
a minimum distance between orthographic projections on the substrate of two adjacent isolation openings is a second spacing, and the third spacing is less than the second spacing; or
a minimum distance between orthographic projections on the substrate of the sub-openings corresponding to two adjacent and connected sub-encapsulation portions in the same light-emitting unit is a first spacing, and the first spacing is less than the third spacing.

7. The display panel of claim 2, wherein the isolation structure comprises an isolation portion located between two adjacent isolation openings, and an orthographic projection on the substrate of the isolation portion located between two adjacent light-emitting units with the same color is located within an orthographic projection on the substrate of the encapsulation portion corresponding to two light-emitting units.

8. The display panel of claim 1, wherein the plurality of sub-openings in the same isolation opening have the same area of orthographic projection on the substrate.

9. The display panel of claim 1, wherein orthographic projections on the substrate of the at least two sub-openings are polygonal, and long sides of the orthographic projections on the substrate of the at least two sub-openings extend along the same direction.

10. The display panel of claim 9, wherein the display panel comprises a scan signal line extending along a preset direction, the long sides of the orthographic projections on the substrate of the sub-openings extend along the preset direction, or the long sides of the orthographic projections on the substrate of the sub-openings extend along a direction perpendicular to the preset direction.

11. The display panel of claim 1, wherein the encapsulation portion comprises sub-encapsulation portions for encapsulating the sub-units, orthographic projections on the substrate of at least two adjacent sub-encapsulation portions are partially overlapped to form an overlapping region, and the overlapping region is located within an orthographic projection of the isolation segment on the substrate.

12. The display panel of claim 11, wherein orthographic projections on the substrate of the encapsulation portions corresponding to at least two adjacent light-emitting units with different light-emitting colors are partially overlapped.

13. The display panel of claim 1, wherein the isolation openings comprise a first isolation opening, a second isolation opening, and a third isolation opening, the light-emitting units comprise a first light-emitting unit corresponding to the first isolation opening, a second light-emitting unit corresponding to the second isolation opening, and a third light-emitting unit corresponding to the third isolation opening, the first isolation opening and the second isolation opening are alternately arranged along a first direction to form a first opening row, a plurality of third isolation openings are sequentially arranged along the first direction to form a second opening row, the first opening row and the second opening row are alternately arranged along a second direction, and the first direction intersects with the second direction;
an orthographic projection of the third isolation opening on the substrate is located within a virtual quadrilateral, centroids of orthographic projections of two of the first isolation openings on the substrate are located at two opposite corners of the virtual quadrilateral, centroids of orthographic projections of two of the second isolation openings on the substrate are located at the other two opposite corners of the virtual quadrilateral, and at least one of the third isolation openings comprises two sub-openings arranged along an extension direction of any diagonal of the virtual quadrilateral.

14. The display panel of claim 2, wherein two adjacent sub-encapsulation portions are connected to each other to form a continuous region, the continuous region is correspondingly disposed on the isolation segment between the sub-openings corresponding to the two adjacent sub-encapsulation portions, and an orthographic projection of the continuous region on the substrate is located within an orthographic projection of the isolation segment on the substrate,
a redundant unit is disposed between the continuous region and the isolation segment, the redundant unit comprises two sub-layers, and wherein a material of one sub-layer is the same as that of the light-emitting sub-structure, and a material of the other sub-layer is the same as that of the second sub-electrode.

15. The display panel of claim 13, wherein at least one of the third light-emitting units comprises two sub-units arranged along the extension direction of the diagonal, at least a portion of the sub-unit of the third light-emitting units is located in the sub-opening of the third isolation opening, the encapsulation portion comprises third sub-encapsulation portions for encapsulating the sub-units of the third light-emitting units, the isolation segment comprises a third isolation segment located in the third isolation opening, the third isolation segment divides the third isolation opening into a plurality of sub-openings, and an orthographic projection of the third isolation segment on the substrate is located within an orthographic projection of the third sub-encapsulation portions on the substrate.

16. The display panel of claim 13, wherein at least one of the first isolation opening and the second isolation opening comprises two sub-openings arranged along the first direction, or at least one of the first isolation opening and the second isolation opening comprises two sub-openings arranged along the second direction.

17. The display panel of claim 16, wherein the first light-emitting unit comprises two sub-units, the encapsulation portion comprises first sub-encapsulation portions for encapsulating the sub-units of the first light-emitting units, the isolation segments comprise a first isolation segment located in the first isolation opening, the first isolation segment is configured to divide the first isolation opening into two sub-openings, and an orthographic projection of the first isolation segment on the substrate is located within an orthographic projection of the first sub-encapsulation portion on the substrate.

18. The display panel of claim 13, wherein at least one of the first isolation opening and the second isolation opening comprises four sub-openings arranged in two rows and two columns along a third direction and a fourth direction, and the first direction, the second direction, the third direction, and the fourth direction intersect in pairs and are in the same plane.

19. The display panel of claim 18, wherein the first light-emitting unit comprises four sub-units arranged in two rows and two columns along the third direction and the fourth direction, the encapsulation portion comprises first sub-encapsulation portions for encapsulating the sub-units of the first light-emitting units, the isolation segments comprise a first isolation segment located in the first isolation openings, the first isolation segment is configured to divide the first isolation opening into four sub-openings, and an orthographic projection of at least a portion of the first isolation segment on the substrate is located within an orthographic projection of the first sub-encapsulation portion on the substrate;
wherein the first direction is perpendicular to the second direction, and the third direction is perpendicular to the fourth direction.

20. The display panel of claim 1, wherein the isolation openings comprise a first isolation opening, a second isolation opening, and a third isolation opening, the light-emitting units comprise a first light-emitting unit corresponding to the first isolation opening, a second light-emitting unit corresponding to the second isolation opening, and a third light-emitting unit corresponding to the third isolation opening, a plurality of first isolation openings are disposed separately along a second direction to form a first opening column, a plurality of second isolation openings are disposed separately along the second direction to form a second opening column, a plurality of third isolation openings are disposed separately along the second direction to form a third opening column, the first opening column, the second opening column, and the third opening column are sequentially and alternately arranged along a first direction, and the first direction intersect with the second direction,
wherein at least one of the first isolation opening, the second isolation opening, and the third isolation opening comprises two or more sub-openings disposed separately.

21. The display panel of claim 20, wherein a dimension of the first isolation opening in the second direction is greater than a dimension of the first isolation opening in the first direction, the first isolation opening comprises two or more sub-openings arranged along the second direction, the first light-emitting unit comprises two or more sub-units disposed separately along the second direction, the encapsulation portion comprises first sub-encapsulation portions for encapsulating the sub-units of the first light-emitting units, the isolation segments comprise a first isolation segment located in the first isolation opening, the first isolation segment is configured to divide the first isolation opening into two or more sub-openings disposed separately along the second direction, and an orthographic projection of the first isolation segment on the substrate is located within an orthographic projection of the first sub-encapsulation portions on the substrate.

22. The display panel of claim 1, wherein the isolation openings comprise a first isolation opening, a second isolation opening, and a third isolation opening, the light-emitting units comprise a first light-emitting unit corresponding to the first isolation opening, a second light-emitting unit corresponding to the second isolation opening, and a third light-emitting unit corresponding to the third isolation opening, the first isolation opening and the third isolation opening are alternately arranged along a second direction to form a fourth opening column, a plurality of second isolation openings are sequentially arranged along the second direction to form a fifth opening column, the fourth opening column and the fifth opening column are alternately arranged along a first direction, one of the first isolation openings and one of the third isolation openings in the fourth opening column are arranged along the first direction with the same second isolation opening in the fifth opening column, and the first direction intersects with the second direction;
wherein at least one of the first isolation opening, the second isolation opening, and the third isolation opening comprises two or more sub-openings disposed separately.

23. The display panel of claim 22, wherein the second isolation opening comprises two or more sub-openings disposed separately along the second direction, or the second isolation opening comprises four sub-openings arranged in two rows and two columns along the first direction and the second direction; or
the first isolation opening and/or the third isolation opening comprises two or more sub-openings disposed separately along the first direction; or
the first isolation opening and/or the third isolation opening comprises four sub-openings arranged in two rows and two columns along the first direction and the second direction.

24. The display panel of claim 1, wherein the isolation structure comprises a third sub-layer, a first sub-layer, and a second sub-layer sequentially arranged in a direction away from the substrate, an orthographic projection of the first sub-layer on the substrate is located within an orthographic projection of the second sub-layer on the substrate, the third sub-layer comprises a conductive material, and the second sub-electrode is electrically connected with the third sub-layer.

25. The display panel of claim 1, further comprising:
a pixel circuit, disposed on one side of the substrate;
a first insulation layer, located on one side of the pixel circuit away from the substrate,
wherein the first sub-electrode is located on one side of the first insulation layer away from the substrate, the first insulation layer is provided with a connection via, and a plurality of first sub-electrodes corresponding to the same light-emitting unit are electrically connected through the same pixel circuit and the same connection via;
the isolation opening comprises two sub-openings disposed separately, and an orthographic projection of the connection via on the substrate is located between orthographic projections of the light-emitting sub-structures of two adjacent sub-openings on the substrate; or
the isolation opening comprises four sub-openings arranged in two rows and two columns, and an orthographic projection of the connection via on the substrate is located at middle of orthographic projections of four of the sub-units of on the substrate.

26. A display panel, comprising:
a substrate;
an isolation structure, located on one side of the substrate, wherein the isolation structure defines and forms an isolation opening, the isolation structure comprises an isolation segment, the isolation segment is disposed within at least one isolation openings and divides the isolation opening into at least two sub-openings;
a light-emitting layer, located on one side of the substrate, wherein the light-emitting layer comprising light-emitting units, at least a portion of the light-emitting unit is located within the isolation opening, at least one of the light-emitting units comprises two or more sub-units disposed separately, at least a portion of the sub-unit is located within the sub-opening, each of the sub-units comprises a first sub-electrode, a light-emitting sub-structure, and a second sub-electrode sequentially stacked in a direction away from the substrate; and
a first encapsulation layer comprising an encapsulation portion for encapsulating the light-emitting units, the encapsulation portion comprising sub-encapsulation portions for encapsulating the sub-units,
wherein the first sub-electrodes of a plurality of sub-units in the same light-emitting unit are electrically connected to each other, and an orthographic projection of the isolation segment on the substrate is partially overlapped with an orthographic projection of the sub-encapsulation portion on the substrate.

27. A display device, comprising the display panel of claim 1.
